(19) United States
(12) Patent Application Publication
(10) Pub. No.: US 2022/0344164 A1
(43) Pub. Date: Oct. 27, 2022

(54) MACHINE LEARNING DEVICE, SUBSTRATE PROCESSING DEVICE, TRAINED MODEL, MACHINE LEARNING METHOD, AND MACHINE LEARNING PROGRAM

(71) Applicant: EBARA CORPORATION, Tokyo (JP)

(72) Inventors: Akira NAKAMURA, Tokyo (JP); Takamasa NAKAMURA, Tokyo (JP); Tsuneo TORIKOSHI, Tokyo (JP); Hirofumi OTAKI, Tokyo (JP)

(21) Appl. No.: 17/761,464

(22) PCT Filed: Sep. 10, 2020
(86) PCT No.: PCT/JP2020/034234

§ 371 Date: Mar. 17, 2022

(30) Foreign Application Priority Data
Sep. 18, 2019 (JP) 2019-169007

(51) Int. Cl. H01L 21/304; G06K 9/62; G06N 20/00; H01L 21/02

(52) U.S. Cl. CPC H01L 21/304; G06K 9/6262; G06N 20/00; H01L 21/02096

(57) ABSTRACT

A device includes: state information acquisition unit that acquires state information including position of substrate in the device and elapsed time in each unit; action selection unit having prediction model that predicts value, in a certain state, to performing action whether to take out new substrate from the cassette and to which processing unit substrate is transferred, the action selection unit selecting one action based on the prediction model taking, as input, the acquired state information; instruction signal transmission unit that transmits instruction signal so as to perform the selected action; operation result acquisition unit that acquires operation result including number of substrates processed and waiting time; and prediction model update unit that calculates reward based on acquired operation result such that reward increases as the number of substrates processed increases and waiting time is short and that updates the prediction model based on the reward.

### TECHNICAL FIELD

The present disclosure relates to a machine learning device, a substrate processing device, a trained model, a machine learning method, and a machine learning program.

### BACKGROUND

As a wire forming process of a semiconductor device, a process (so-called damascene process) is known in which a metal (wire material) is embedded in a wire groove and a via hole. This is a process technology in which metals such as aluminum, copper, and silver are embedded in wire grooves and via holes that are pre-formed in an interlayer insulating film, and then an excess metal is removed for planarization by chemical mechanical polishing (CMP).

FIGS. 1A to 1D are diagrams showing examples of copper wire formation in a semiconductor device in order of processes. First, as illustrated in FIG. 1A, an insulating film (interlayer insulating film) 2 such as an oxide film made of SiO₂ or a low-k material film is deposited on a conductive layer la on a semiconductor base material 1 on which a semiconductor element is formed, a via hole 3 and a wire groove 4 as micro-recesses for wiring are formed in the inside of the insulating film 2 by, for example, lithography etching technology, and a barrier layer 5 made of TaN or the like is formed on the via hole 3 and the wire groove 4, and a seed layer 6 as a power feeding layer in electric field plating is formed on the barrier layer 5 by sputtering or the like.

Then, as illustrated in FIG. 1B, copper plating is applied to the surface of a substrate (polishing target) W, copper is filled in the via hole 3 and the wire groove 4 of a substrate W, and a copper film 7 is deposited on the insulating film 2. After that, as illustrated in FIG. 1C, the seed layer 6 and the copper film 7 on the barrier layer 5 are removed by chemical mechanical polishing (CMP) or the like to expose the surface of the barrier layer 5, and further, as illustrated in FIG. 1D, the barrier layer 5 on the insulating film 2 and, as necessary, a part of the surface layer of the insulating film 2 are removed, and a wire (copper wire) 8 formed of the seed layer 6 and the copper film 7 in the inside of the insulating film 2 is formed.

In order to improve the throughput in the polishing process, a polishing device with two polishing units and one cleaning unit is developed. In such a polishing device, the polished substrate (polishing target) is sequentially supplied from two polishing units to one cleaning unit. In this case, once one substrate enters the cleaning process, the other substrates are not permitted to enter the cleaning process until the cleaning process is ended. As a result, it is not possible to start cleaning a polished substrate immediately after polishing, and a situation occurs in which cleaning has to wait until cleaning of the previous substrate is ended.

Here, in the metal film polishing process, for example, in the copper film polishing process in the copper wire forming process, when the polished substrate is left wet as it is after the polishing is ended, the corrosion of copper that forms copper wires on the substrate surface proceeds. Since copper forms wires in semiconductor circuits, the corrosion leads to an increase in wire resistance.

In order to slow the progress of corrosion of the copper constituting the copper wire from the end of polishing to the start of cleaning, pure water is supplied to the substrate surface to avoid direct exposure of the surface of the substrate after polishing to the atmosphere, which is common practice. However, this method fails to sufficiently suppress the corrosion of copper. In order to suppress the corrosion of copper more effectively, it is demanded to shorten the time itself from the end of polishing to the start of cleaning as much as possible.

Conventionally, for example, in a substrate processing device, there is proposed a scheduler that manages the processes of transfer, processing, and cleaning of substrates according to a predetermined time chart. JP 5023146 B2 proposes that an average polishing time in a first polishing unit and a second polishing unit, an average transfer time in a transfer mechanism, and an average cleaning time in a cleaning unit are stored in advance and at the time of creating a time chart, polishing start time at the first polishing unit and the second polishing unit is determined such that time from the end of polishing to the start of cleaning of a substrate is minimized based on the average polishing time, the average transfer time, and the average cleaning time stored in advance.

### SUMMARY

However, according to the knowledge of the present inventors, the method of controlling processes according to a predetermined time chart has inconveniences below. That is, since the polishing time in the polishing unit is determined by detecting an end point, variations are present in the polishing time. This is because the end point is detected by different recipes for different products, and there is a correlation between the polishing time and the use time of a consumable member even in the same recipe. In addition, variations are present in the operating time of each unit due to mechanical variations. In addition, an interlock is present in the operation between specific units, and the units may not operate arbitrarily. In addition, a plurality of processing routes may coexist. In addition, a specific unit may fail to cause a suspension may occur. Therefore, for example, in the case in which the average transfer time is X seconds while the actual operation time is delayed by 0.5 seconds, the time chart may shift backwards, resulting in a large delay in the subsequent operation.

It is desired to provide a machine learning device, a substrate processing device, a trained model, a machine learning method, and a machine learning program that are capable of appropriately determining the timing of starting transfer of a substrate and a transfer route according to a state from one time to another in the device. In addition, it is desired to provide a machine learning device, a substrate processing device, a trained model, a machine learning method, and a machine learning program that are capable of appropriately determining the timing of starting transfer of a substrate according to a state from one time to another in the device in the case in which the transfer route of the substrate is predetermined. In addition, it is desired to provide a machine learning device, a substrate processing device, a trained model, a machine learning method, and a machine learning program that are capable of accurately predicting surface treatment time in a processing unit.

A machine learning device according to an aspect of the present disclosure is a machine learning device that performs machine learning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit,

or to a simulator of the substrate processing device, the machine learning device including:

a state information acquisition unit that acquires state information including a position of a substrate in the substrate processing device and an elapsed time of a substrate located in each unit in a relevant unit;

an action selection unit having a prediction model that predicts a value, in a certain state, to performing an action whether to take out a new substrate from the cassette and a value to which one of the first processing unit and the second processing unit a new substrate is transferred when a new substrate is taken out, the action selection unit selecting one action based on the prediction model taking, as an input, the state information acquired by the state information acquisition unit;

an instruction signal transmission unit that transmits an instruction signal to the control unit so as to perform the action selected by the action selection unit;

an operation result acquisition unit that acquires, after finishing processing a predetermined number of substrates, an operation result including number of substrates processed per unit time and a waiting time that elapses until cleaning of a substrate after surface treatment is started in the cleaning unit; and

a prediction model update unit that calculates a reward based on an operation result acquired by the operation result acquisition unit such that a reward increases as the number of substrates processed increases and the waiting time becomes shorter and that updates the prediction model based on the reward.

### BRIEF DESCRIPTION OF DRAWINGS

FIG. 1A is a diagram that illustrates an example of copper wire formation in a semiconductor device in order of processes.

FIG. 1B is a diagram that illustrates an example of copper wire formation in a semiconductor device in order of processes.

FIG. 1C is a diagram that illustrates an example of copper wire formation in a semiconductor device in order of processes.

FIG. 1D is a diagram that illustrates an example of copper wire formation in a semiconductor device in order of processes.

FIG. 2 is a plan view that illustrates an outline of the overall configuration of a substrate processing device according to an embodiment.

FIG. 3 is a configuration diagram that illustrates an outline of the substrate processing device illustrated in FIG. 2.

FIG. 4 is a time chart when the substrate processing device illustrated in FIG. 2 is controlled at a control unit such that throughput is maximized.

FIG. 5 is a block diagram that illustrates a configuration of a machine learning device according to a first embodiment.

FIG. 6 is a schematic diagram that explains an example of a configuration of a prediction model according to the first embodiment.

FIG. 7 is a flowchart that illustrates an example of a machine learning method according to the first embodiment.

FIG. 8 is a block diagram that illustrates a configuration of a machine learning device according to a second embodiment.

FIG. 9 is a schematic diagram that explains a configuration of a prediction model according to the second embodiment.

FIG. 10 is a flowchart that illustrates an example of a machine learning method according to the second embodiment.

FIG. 11 is a block diagram that illustrates a configuration of a machine learning device according to a third embodiment.

FIG. 12 is a schematic diagram that explains a configuration of a prediction model according to the third embodiment.

FIG. 13 is a flowchart that illustrates an example of a machine learning method according to the third embodiment.

### DESCRIPTION OF EMBODIMENTS

A machine learning device according to a first aspect of the embodiment is a machine learning device that performs machine learning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit,

or to a simulator of the substrate processing device, the machine learning device comprising:

a state information acquisition unit that acquires state information including a position of a substrate in the substrate processing device and an elapsed time of a substrate located in each unit in a relevant unit;

an action selection unit having a prediction model that predicts a value, in a certain state, to performing an action whether to take out a new substrate from the cassette and a value to which one of the first processing unit and the second processing unit a new substrate is transferred when a new substrate is taken out, the action selection unit selecting one action based on the prediction model taking, as an input, the state information acquired by the state information acquisition unit;

an instruction signal transmission unit that transmits an instruction signal to the control unit so as to perform the action selected by the action selection unit;

an operation result acquisition unit that acquires, after finishing processing a predetermined number of substrates, an operation result including a number of substrates processed per unit time and a waiting time that elapses until cleaning of a substrate after surface treatment is started in the cleaning unit; and

a prediction model update unit that calculates a reward based on an operation result acquired by the operation result acquisition unit such that a reward increases as the number of substrates processed increases and the waiting time becomes shorter and that updates the prediction model based on the reward.

According to such an aspect, the machine learning device performs try and error to select an action whether to take out a new substrate from the cassette and an action to which one of the first processing unit and the second processing unit a new substrate is transferred when a new substrate is taken out, according to the state information including the position of the substrate from one time to another in the substrate processing device and the elapsed time of the substrate in the units in the relevant unit, based on the prediction model, after processing of a predetermined number of substrates is ended, a large reward is obtained as the number of processed substrates per unit time is larger and the waiting time that elapses until cleaning of the surface-treated substrate is started is shorter, and the prediction model is updated based on the reward, and the processes are repeated, and thus machine learning (reinforcement learning) of the prediction model is performed. As a result, with the use of the trained prediction model created by such a machine learning device, the timing of starting transfer of the substrate and the transfer route can be appropriately determined according to the state from one time to another in the substrate processing device (such that the number of processed substrates per unit timer is large and the waiting time is short).

A machine learning device according to a second aspect of the embodiment is the machine learning device according to the first aspect, in which

the first processing unit and the second processing unit are polishing units that polish a substrate.

A machine learning device according to a third aspect of the embodiment is the machine learning device according to the first or the second aspects, in which

the state information further includes use time of a consumable member used in the first processing unit and the second processing unit.

A machine learning device according to a fourth aspect of the embodiment is the machine learning device according to the third aspect which cites the second aspect, in which

the consumable member is one or two or more of a polishing pad attached to a rotary table, a retainer ring attached to a top ring, the retainer ring supporting an outer edge of the substrate, and an elastic film attached to the top ring, the elastic film supporting a back surface of the substrate.

A machine learning device according to a fifth aspect of the embodiment is the machine learning device according to any one of the first to fourth aspects, in which the state information further includes recipe information on treatment applied in advance to the substrate housed in the cassette.

A machine learning device according to a sixth aspect of the embodiment is the machine learning device according to any one of the first to fifth aspects, in which

the state information further includes failure occurrence information or continuous operation time of the first processing unit and the second processing unit.

A machine learning device according to a seventh aspect of the embodiment is the machine learning device according to any one of the first to sixth aspects, in which

the state information further includes recipe information on surface treatment in the first processing unit and the second processing unit.

A substrate processing device according to an eighth aspect of the embodiment is

a substrate processing device including:

a mounting unit on which a cassette that houses a plurality of substrates is mounted;

a first processing unit and a second processing unit that surface-treat a substrate;

a cleaning unit that cleans a substrate after surface treatment;

a transfer unit that transfers a substrate between the mounting unit, the first processing unit and the second processing unit, and the cleaning unit; and

a control unit that controls operations of the first processing unit, the second processing unit, the cleaning unit, and the transfer unit, wherein

the control unit has a trained model created by the machine learning device according to any one of aspects 1 to 7, the control unit selects an action whether to take out a new substrate from the cassette and to which one of the first processing unit and the second processing unit the new substrate is transferred when taking out the new substrate from the cassette, taking, as an input, state information including a position of a substrate in the substrate processing device and an elapsed time of a substrate in the units in a relevant unit based on the trained model, and the control unit controls an operation of the transfer unit so as to perform the selected action.

A trained model (tuned neural network system) according to a ninth aspect of the embodiment is

a trained model created by performing machine leaning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit,

or to a simulator of the substrate processing device, the trained model including:

an input layer, one or more intermediate layers connected to the input layer, and an output layer connected to the intermediate layer, wherein

the trained model is subjected to reinforcement learning on timing of starting transfer of a substrate and a transfer route of the substrate in which

state information including a position of a substrate in the substrate processing device and an elapsed time of a substrate located in each unit in the relevant unit is acquired, the acquired state information is input to the input layer, based on the input then output from the output layer, the value to performing an action whether to take out a new substrate from the cassette, and to which one of the first processing unit and the second processing unit a new substrate is transferred when a new substrate is taken out, one action is selected, an operation of the transfer unit is controlled so as to perform the selected action, after processing of a predetermined number of substrates is ended, an operation result including a number of substrates processed per unit time and a waiting time that elapses until cleaning of a surface-treated substrate is started in the cleaning unit is acquired, a reward is calculated based on the acquired operation result such that the reward increases as the number of substrates processed is large and the waiting time is short, a process of updating a parameter of each node is repeated based on the reward, so that the number of substrates processed is large and the waiting time is short, and

the learned model causes a computer to function to predict, upon inputting state information including a position of a substrate in the substrate processing device and an elapsed time of a substrate located in each unit in a relevant unit to the input layer, a value to performing an action whether to take out a new substrate from the cassette, and to which one of the first processing unit and the second processing unit a new substrate is transferred when a new substrate is taken out and output the value from the output layer.

A machine learning method according to a tenth aspect of the embodiment is

a machine learning method executed by a computer to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit,

or to a simulator of the substrate processing device, the machine learning method including:

a state information acquisition step of acquiring state information including a position of a substrate in the substrate processing device and an elapsed time of a substrates located in each unit in a relevant unit;

an action selecting step of selecting one action based on a prediction model that predicts a value, in a certain state, to performing an action whether to take out a new substrate from the cassette and a value to which one of the first processing unit and the second processing unit the new substrate is transferred when the new substrate is taken out, taking, as an input, the state information acquired by the state information acquisition step;

an instruction signal transmission step of transmitting an instruction signal to the control unit so as to perform the action selected by the action selection step;

an operation result acquisition step of acquiring, after finishing processing a predetermined number of substrates, an operation result including a predetermined number of substrates processed per unit time and a waiting time that elapses until cleaning of a substrate after surface treatment is started in the cleaning unit; and

a prediction model update step of calculating a reward based on an operation result acquired in the operation result acquisition step such that a reward increases as the number of substrates processed increases and the waiting time is short and updating the prediction model based on the reward.

A machine learning program according to an eleventh aspect of the embodiment is

a machine learning program that causes a computer to perform machine learning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit,

or to a simulator of the substrate processing device, the machine learning program that causes the computer to function as

a state information acquisition unit that acquires state information including a position of a substrate in the substrate processing device and an elapsed time of a substrate located in each unit in a relevant unit;

an action selection unit having a prediction model that predicts a value, in a certain state, to performing an action whether to take out a new substrate from the cassette and a value to which one of the first processing unit and the second processing unit a new substrate is transferred when a new substrate is taken out, the action selection unit selecting one action based on a value function taking, as an input, the state information acquired by the state information acquisition unit,

an instruction signal transmission unit that transmits an instruction signal to the control unit so as to perform the action selected by the action selection unit;

an operation result acquisition unit that acquires, after finishing processing a predetermined number of substrates, an operation result including a number of substrates processed per unit time and a waiting time that elapses until cleaning of a substrate after surface treatment is started in the cleaning unit; and

a prediction model update unit that calculates a reward based on an operation result acquired by the operation result acquisition unit such that a reward increases as the number of substrates processed increases and the waiting time becomes shorter and that updates the prediction model based on the reward.

A machine learning device according to a twelfth aspect of the embodiment is

a machine learning device that performs machine learning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit according to a transfer rule defining a correspondence between an order of substrates taken out from the cassette and to which one of the first processing unit and the second processing unit a substrate is transferred,

or to a simulator of the substrate processing device, the machine learning device including:

a state information acquisition unit that acquires state information including a position of a substrate in the substrate processing device and an elapsed time of a substrate located in each unit in a relevant unit;

an action selection unit having a prediction model that predicts a value, in a certain state, to performing an action whether to take out a new substrate from the cassette, the action selection unit selecting one action based on the prediction model taking, as an input, the state information acquired by the state information acquisition unit;

an instruction signal transmission unit that transmits an instruction signal to the control unit so as to perform the action selected by the action selection unit;

an operation result acquisition unit that acquires, after finishing processing a predetermined number of substrates, an operation result including a number of substrates processed per unit time; and

a prediction model update unit that calculates a reward based on an operation result acquired by the operation result acquisition unit such that a reward increases as the number of substrates processed increases and that updates the prediction model based on the reward.

According to such an aspect, the machine learning device performs try and error to select an action whether to take out a new substrate from the cassette according to the state information including the position of the substrate from one time to another in the substrate processing device and the elapsed time of the substrate in the units in the relevant unit, based on the prediction model, after processing of a predetermined number of substrates is ended, a large reward is obtained as the number of processed substrates per unit time is larger, the prediction model is updated based on the reward, and the processes are repeated, and thus machine learning (reinforcement learning) of the prediction model is performed. As a result, with the use of the trained prediction model created by such a machine learning device, it is possible to appropriately determine the timing of starting transfer of the substrate can be set according to the state from one time to another in the device (to increase the number of processed substrates per unit time).

A machine learning device according to a thirteenth aspect of the embodiment is the machine learning device according to the twelfth aspect, in which the first processing unit and the second processing unit are polishing units that polish a substrate.

A machine learning device according to a fourteenth aspect of the embodiment is the machine learning device according to the twelfth or thirteenth aspect, in which the state information further includes use time of a consumable member used in the first processing unit and the second processing unit.

A machine learning device according to a fifteenth aspect of the embodiment is the machine learning device according to the fourteenth aspect which cites the thirteenth aspect, in which

the consumable member is one or two or more of a polishing pad attached to a rotary table, a retainer ring attached to a top ring, the retainer ring supporting an outer edge of the substrate, and an elastic film attached to the top ring, the elastic film supporting a back surface of the substrate.

A machine learning device according to a sixteenth aspect of the embodiment is the machine learning device according to any one of the twelfth to fifteenth aspects, in which

the state information further includes recipe information on treatment applied in advance to the substrate housed in the cassette.

A machine learning device according to a seventeenth aspect of the embodiment is the machine learning device according to any one of the twelfth to sixteenth aspects, in which

the state information further includes continuous operation time of the first processing unit and the second processing unit.

A machine learning device according to an eighteenth aspect of the embodiment is the machine learning device according to any one of the twelfth to seventeenth aspects, in which

the state information further includes recipe information on surface treatment in the first processing unit and the second processing unit.

A substrate processing device according to a nineteenth aspect of the embodiment is

a substrate processing device including:

a mounting unit on which a cassette that houses a plurality of substrates is mounted;

a first processing unit and a second processing unit that surface-treat a substrate;

a cleaning unit that cleans a substrate after surface treatment;

a transfer unit that transfers a substrate between the mounting unit, the first processing unit and the second processing unit, and the cleaning unit; and

a control unit that controls operations of the first processing unit, the second processing unit, the cleaning unit, and the transfer unit according to a transfer rule defining a correspondence between an order of substrates taken out from the cassette and to which one of the first processing unit and the second processing unit a substrate is transferred, wherein

the control unit has a trained model created by the machine learning device according to any one of claims 12 to 18, the control unit selects an action whether to take out a new substrate from the cassette, taking, as an input, state information including a position of a substrate in the substrate processing device and an elapsed time of a substrate in the units in a relevant unit based on the trained model, and the control unit controls an operation of the transfer unit so as to perform the selected action.

A trained model (tuned neural network system) according to a twentieth aspect of the embodiment is

a trained model created by performing machine leaning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit according to a transfer rule defining a correspondence between an order of substrates taken out from the cassette and to which one of the first processing unit and the second processing unit a substrate is transferred,

or to a simulator of the substrate processing device, the trained model including:

an input layer, one or more intermediate layers connected to the input layer, and an output layer connected to the intermediate layer, wherein

the trained model is subjected to reinforcement learning on timing of starting transfer of a substrate in which

state information including a position of a substrate in the substrate processing device and an elapsed time of a substrate located in each unit in the relevant unit is acquired, the acquired state information is input to the input layer,

based on the input then output from the output layer, the value to performing an action whether to take out a new substrate from the cassette, one action is selected, an operation of the transfer unit is controlled so as to perform the selected action, after processing of a predetermined number of substrates is ended, an operation result including a number of substrates processed per unit time is acquired, a reward is calculated based on the acquired operation result such that the reward increases as the number of substrates processed is large, a process of updating a parameter of each node is repeated based on the reward, so that the number of substrates processed is large, and

the trained model causes a computer to function to predict, upon inputting state information including a position of a substrate in the substrate processing device and an elapsed time of a substrate located in each unit in a relevant unit to the input layer, a value to performing an action whether to take out a new substrate from the cassette, and output the value from the output layer.

A machine learning method according to a twenty-first aspect of the embodiment is

a machine learning method executed by a computer to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit according to a transfer rule defined with a correspondence between an order of substrates taken out from the cassette and to which one of the first processing unit and the second processing unit a substrate is transferred,

or to a simulator of the substrate processing device, the machine learning method including:

a state information acquisition step of acquiring state information including a position of a substrate in the substrate processing device and an elapsed time of a substrates located in each unit in a relevant unit;

an action selecting step of selecting one action based on a prediction model that predicts a value, in a certain state, to performing an action whether to take out a new substrate from the cassette, taking, as an input, the state information acquired by the state information acquisition step;

an instruction signal transmission step of transmitting an instruction signal to the control unit so as to perform the action selected by the action selection step;

an operation result acquisition step of acquiring, after finishing processing a predetermined number of substrates, an operation result including a number of substrates processed per unit time; and

a prediction model update step of calculating a reward based on an operation result acquired in the operation result acquisition step such that a reward increases as the number of substrates processed increases and updating the prediction model based on the reward.

A machine learning program according to a twenty-second aspect of the embodiment is

a machine learning program that causes a computer to function to perform machine learning to a substrate processing device having

a mounting unit on which a cassette that houses a plurality of substrates is mounted,

a first processing unit and a second processing unit that surface-treat a substrate,

a cleaning unit that cleans a substrate after surface treatment,

a transfer unit that transfers a substrate between the mounting unit, the first processing unit and the second processing unit, and the cleaning unit, and

a control unit that controls operations of the first processing unit, the second processing unit, the cleaning unit, and the transfer unit according to a transfer rule defined with a correspondence between an order of substrates taken out from the cassette and to which one of the first processing unit and the second processing unit a substrate is transferred,

or to a simulator of the substrate processing device, the machine learning program that causes the computer to function as

a state information acquisition unit that acquires state information including a position of a substrate in the substrate processing device and an elapsed time of a substrate located in each unit in a relevant unit;

an action selection unit having a prediction model that predicts a value, in a certain state, to performing an action whether to take out a new substrate from the cassette, the action selection unit selecting one action based on the prediction model taking, as an input, the state information acquired by the state information acquisition unit;

an instruction signal transmission unit that transmits an instruction signal to the control unit so as to perform the action selected by the action selection unit;

an operation result acquisition unit that acquires, after processing of a predetermined number of substrates is ended, an operation result including a number of substrates processed per unit time; and

a value function update unit that calculates a reward based on an operation result acquired by the operation result acquisition unit such that a reward increases as the number of substrates processed increases and that updates the prediction model based on the reward.

A machine learning device according to a twenty-third aspect of the embodiment is

a machine learning device that machine-learns a relation between recipe information on surface treatment in a processing unit that surface-treats a substrate, substrate information, use time of a consumable member used in the processing unit, continuous operation time of the processing unit, and actual surface treatment time in the processing unit, the machine learning device including:

an input information acquisition unit that acquires, as input information, recipe information on surface treatment in the processing unit, substrate information, use time of a consumable member used in the processing unit, and continuous operation time of the processing unit;

a prediction unit having a prediction model that predict surface treatment time in the processing unit based on recipe information on surface treatment in the processing unit, substrate information, use time of a consumable member used in the processing unit, and continuous operation time of the processing unit, the prediction unit predicting surface treatment time in the processing unit, taking, as an input, input information acquired by the input information acquisition unit, based on the prediction model;

an actual surface treatment time acquisition unit that acquires actual surface treatment time in the processing unit; and

a prediction model update unit that updates the prediction model according to an error between actual surface treatment time acquired by the actual surface treatment time acquisition unit and surface treatment time predicted by the prediction unit.

According to such an aspect, the machine learning device performs machine learning (supervised learning) of the prediction model using the correspondence between recipe information of surface treatment in the processing unit, substrate information, use time of a consumable member used in the processing unit, continuous operation time of the processing unit, and actual surface processing time in the processing unit as teacher data. As a result, with the use of the trained prediction model created by such a machine learning device, it is possible to accurately predict the surface treatment time in the processing unit in consideration of the recipe information of the surface treatment in the processing unit and the substrate information as well as use time of a consumable member used in the processing unit and the continuous operation time of the processing unit, and thus it is possible to accurately determine the timing of starting transfer of the substrate based on the predicted surface treatment time at the time of creating a time chart.

A machine learning device according to a twenty-fourth aspect of the embodiment is the machine learning device according to the twenty-third aspect, in which

the processing unit is a polishing unit that polishes a substrate.

A machine learning device according to a twenty-fifth aspect of the embodiment is the machine learning device according to the twenty-fourth aspect, in which

the consumable member is one or two or more of a polishing pad attached to a rotary table, a retainer ring attached to a top ring, the retainer ring supporting an outer edge of the substrate, and an elastic film attached to the top ring, the elastic film supporting a back surface of the substrate.

A substrate processing device according to a twenty-sixth aspect of the embodiment is

a substrate processing device including:

a mounting unit on which a cassette that houses a plurality of substrates is mounted;

a first processing unit and a second processing unit that surface-treat a substrate;

a cleaning unit that cleans a substrate after surface treatment;

a transfer unit that transfers a substrate between the mounting unit, the first processing unit and the second processing unit, and the cleaning unit; and

a control unit that controls operations of the first processing unit, the second processing unit, the cleaning unit, and the transfer unit, according to a transfer rule defined with a correspondence between an order of substrates taken out from the cassette, to which one of the first processing unit and the second processing unit a substrate is transferred, and transfer start time of a substrate, wherein

the control unit has a trained model created by the machine learning device according to any one of claims 23 to 25, the control unit predicts, on substrates housed in the cassette, surface treatment time in the first processing unit or the second processing unit, taking, as an input, recipe information on surface treatment in the first processing unit or the second processing unit, substrate information, use time of a consumable member used in the first processing unit or the second processing unit, and continuous operation time of the first processing unit or the second processing unit based on the trained model, and the control unit determines the transfer start time based on the predicted surface treatment time.

A trained model (tuned neural network system) according to a twenty-seventh aspect of the embodiment is

a trained model generated by machine-learning a relation between recipe information on surface treatment in a processing unit that surface-treats a substrate, substrate information, use time of a consumable member used in the processing unit, continuous operation time of the processing unit, and actual surface treatment time in the processing unit, the trained model including

an input layer, one or more intermediate layers connected to the input layer, and an output layer connected to the intermediate layer, wherein

a process is repeated in which recipe information on surface treatment in the processing unit, substrate information, use time of a consumable member used in the processing unit, and continuous operation time of the processing unit are input to the input layer to thereby output an output result from the output layer, the output result is compared with actual surface treatment time in the processing unit, and a parameter of each unit is updated according to an error from the comparison, and the trained model machine-learns a relation between recipe information on surface treatment in the processing unit, substrate information, use time of a consumable member used in the processing unit, and continuous operation time of the processing unit, and actual surface treatment time in the processing unit, and

the trained model causes a computer to function to,

upon inputting recipe information on surface treatment in the processing unit, substrate information, use time of a consumable member used in the processing unit, and continuous operation time of the processing unit to the input layer, predict surface treatment time in the processing unit and output the surface treatment time to the output layer.

A machine learning method according to a twenty-eight aspect of the embodiment is

a machine learning method executed by a computer that machine-learns a relation between recipe information on surface treatment in a processing unit that surface-treats a substrate, substrate information, use time of a consumable member used in the processing unit, continuous operation time of the processing unit, and actual surface treatment time in the processing unit, the method including:

an input information acquisition step of acquiring, as input information, recipe information on surface treatment in the processing unit, substrate information, use time of a consumable member used in the processing unit, and continuous operation time of the processing unit;

a prediction step of predicting surface treatment time in the processing unit, using a prediction model that predicts surface treatment time in the processing unit based on recipe information on surface treatment in the processing unit, substrate information, use time of a consumable member used in the processing unit, and continuous operation time of the processing unit, taking, as an input, input information acquired in the input information acquisition step based on the prediction model;

an actual surface treatment time acquisition step of acquiring actual surface treatment time in the processing unit; and

a trained model update step of updating the prediction model according to according to an error between actual surface treatment time acquired in the actual surface treatment time acquisition step and surface treatment time predicted in the prediction step.

A machine learning program according to a twenty-ninth aspect of the embodiment is

a machine learning program that causes a computer to machine-learns a relation between recipe information on surface treatment in a processing unit that surface-treats a substrate, substrate information, use time of a consumable member used in the processing unit, continuous operation time of the processing unit, and actual surface treatment time in the processing unit, the machine learning program that causes the computer to function as

an input information acquisition unit that acquires, as input information, recipe information on surface treatment in the processing unit, substrate information, use time of a consumable member used in the processing unit, and continuous operation time of the processing unit;

a prediction unit having a prediction model that predict surface treatment time in the processing unit based on recipe information on surface treatment in the processing unit, substrate information, use time of a consumable member used in the processing unit, and continuous operation time of the processing unit, the prediction unit predicting and outputting surface treatment time in the processing unit, taking, as an input, input information acquired by the input information acquisition unit, based on the prediction model;

an actual surface treatment time acquisition unit that acquires actual surface treatment time in the processing unit; and

a prediction model update unit that updates the prediction model according to an error between actual surface treatment time acquired by the actual surface treatment time acquisition unit and surface treatment time predicted by the prediction unit.

In the following, specific examples of an embodiment will be described in detail with reference to the accompanying drawings. It should be noted that in the following description and the drawings used in the following description, parts that are possibly formed in the same configuration are designated with the same reference signs, and the redundant description is omitted.

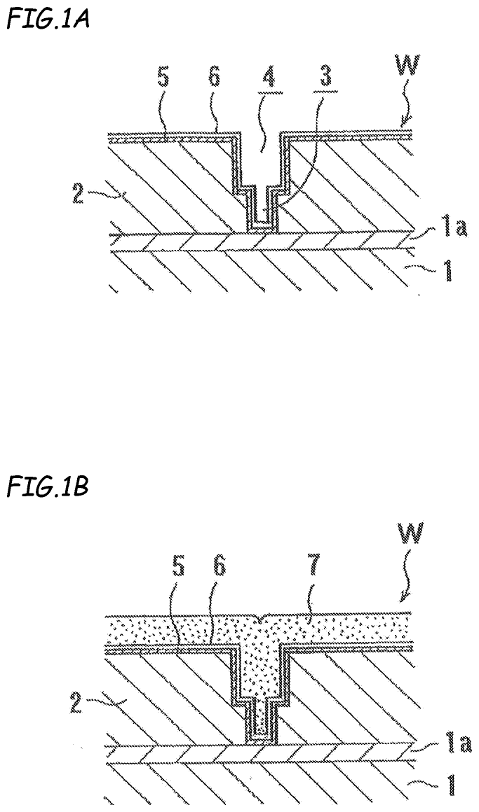

In the embodiments described below, an example of performing two-step polishing will be described in which as illustrated in FIG. 1B, to the substrate W on which the copper film 7 is formed on the surface, as illustrated in FIG. 1C, the copper film 7 and the seed layer 6 on the barrier layer 5 are polished and removed (first polishing) to expose the barrier layer 7, and then, as illustrated in FIG. 1D, the barrier layer 5 on the insulating film 2 and a part of the surface layer of the insulating film 2, as necessary, are polished and removed (second polishing). However, the two-step polishing is merely an example, and it is without saying that the present embodiment is not limited to such two-step polishing.

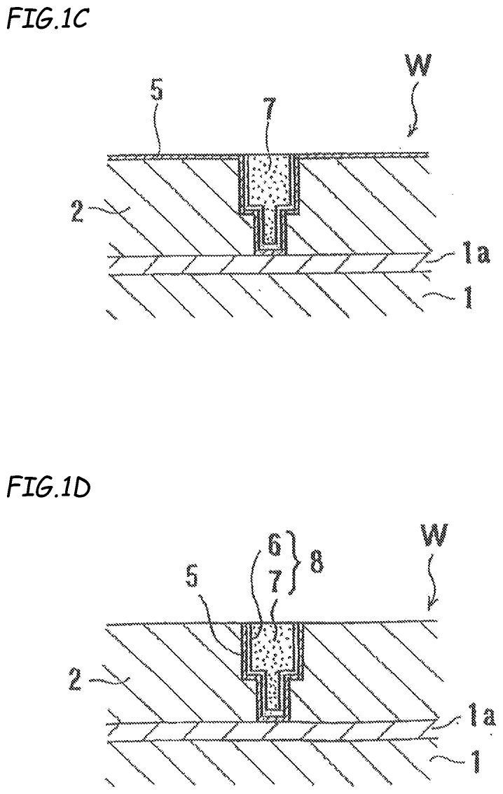

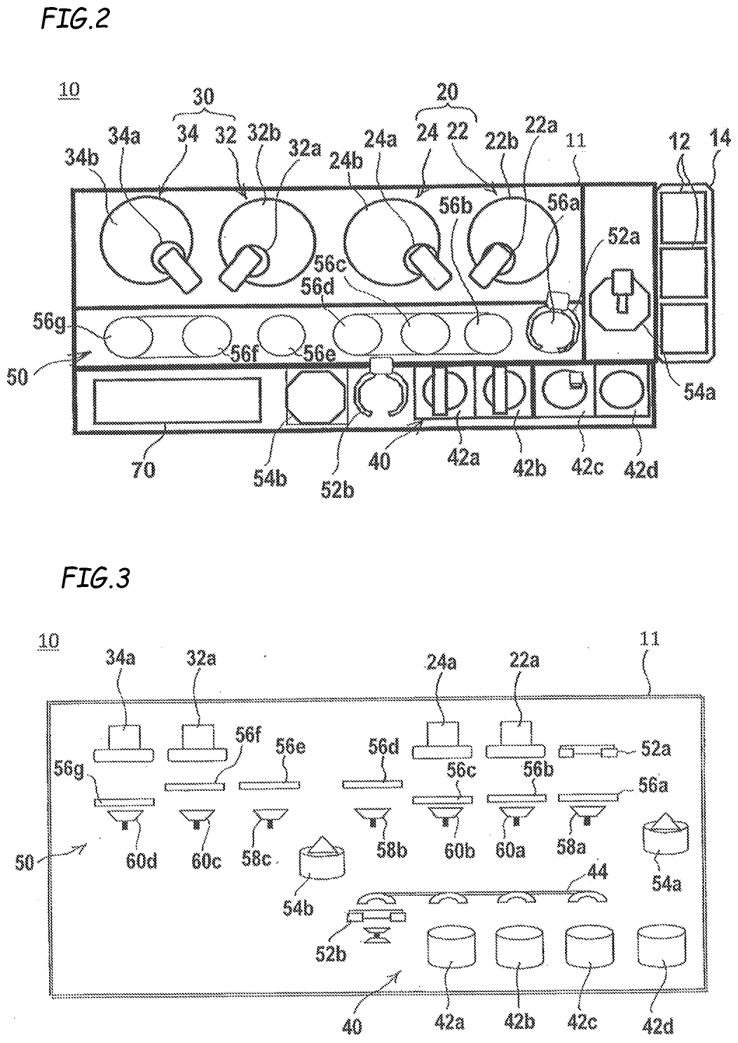

FIG. 2 is a plan view that illustrates an outline of the overall configuration of a substrate processing device 10 according to an embodiment, and FIG. 3 is a configuration diagram that illustrates an outline of the substrate processing device 10 illustrated in FIG. 2.

As illustrated in FIG. 2, the substrate processing device 10 according to the present embodiment is a polishing device, and has a housing 11 in a substantially rectangular shape, a mounting unit 14 on which a plurality (three in the illustrated example) of cassettes 12 is mounted, the cassettes 12 that mount plurality of substrates (polishing targets), a first processing unit 20 and a second processing unit 30 that treat (polish) the surface of the substrate, a cleaning unit 40 that cleans the substrate after surface treatment (polished), a transfer unit 50 that transfers the substrate between the mounting unit 14, the first processing unit 20 and the second processing unit 30, and the cleaning unit 40, a control unit 70 that controls operations of the first processing unit 20 and the second processing unit 30, the cleaning unit 40, and the transfer unit 50.

Among these components, the cassette 12 mounted on the mounting unit 14 is housed in a closed container made of, for example, an SMIF (Standard Manufacturing Interface) pod or an FOUP (Font Opening Unified Pod).

As illustrated in FIG. 2, the first processing unit 20 and the second processing unit 30 are disposed on one side (upper side in FIG. 2) of the inside of the housing 11 along the long-side direction. In the present embodiment, both the first processing unit 20 and the second processing unit 30 are polishing units that polish the substrate.

The first processing unit 20 has a first polishing section 22 and a second polishing section 24. The first polishing section 22 of the first processing unit 20 has a top ring 22a that retains the substrate W detachably, and a rotary table 22b to which a polishing pad having a polishing surface on the surface is attached. The second polishing section 24 has a top ring 24a that retains the substrate W detachably, and a rotary table 24b to which a polishing pad having a polishing surface on the surface is attached. Similarly, the second processing unit 30 has a first polishing section 32 and a second polishing section 34. The first polishing section 32 of the second processing unit 30 has a top ring 32a and a rotary table 32b, and the second polishing section 34 has a top ring 34a and a rotary table 34b.

As illustrated in FIG. 2, the cleaning unit 40 is disposed on the other side (lower side in FIG. 2) of the inside of the housing 10 along the long-side direction. In the illustrated example, the cleaning unit 40 has a first cleaning machine 42a, a second cleaning machine 42b, a third cleaning machine 42c, a fourth cleaning machine 42d, and a transfer mechanism 44 (see FIG. 3). The first to fourth cleaning machines 42a to 42d are disposed in series in this order along the long-side direction of the housing 10. The transfer mechanism 44 (see FIG. 3) has the same number of hands (four in the illustrated example) as the number of the cleaning machines 42a to 42d and is capable of reciprocating movement along the arrangement of the cleaning machines 42a to 42d (i.e., the long-side direction of the housing 10).

As illustrated in FIG. 3, with the reciprocating movement of the transfer mechanism 44, the substrate W is cleaned while being sequentially transferred in the order of the first cleaning machine 42a→the second cleaning machine 42b→the third cleaning machine 42c→the fourth cleaning machine 42d. This cleaning tact (cleaning time) is set at the cleaning time in the cleaning machine having the longest cleaning time among the cleaning machines 42a to 42d, and after the cleaning process in the cleaning machine having the longest cleaning time is ended, the transfer mechanism 44 is driven and the substrate W is transferred.

As illustrated in FIGS. 2 and 3, the transfer unit 50 is disposed in an area sandwiched between the mounting unit 14, the first processing unit 20 and the second processing unit 30, and the cleaning unit 40. In the illustrated example, the transfer unit 50 has a first reversing machine 52a that reverses the substrate W before polishing at an angle of 180°, a second reversing machine 52b that reverses the substrate W after polishing at an angle of 180°, a first transfer robot 54a disposed between the first reversing machine 52a and the mounting unit 14, and a second transfer robot 54b disposed between the second reversing machine 52b and the cleaning unit 40.

As illustrated in FIGS. 2 and 3, between the first processing unit 20 and the cleaning unit 40, a first linear transporter 56a, a second linear transporter 56b, a third linear transporter 56c, and a fourth linear transporter 56d are disposed in this order from the mounting unit 14 side. Among these components, the first reversing machine 52a described above is disposed above the first linear transporter 56a, and a lifter 58a that is capable of being elevated up and down is disposed below the first reversing machine 52a. In addition, a pusher 60a that is capable of being elevated up and down is disposed below the second linear transporter 56b, and a pusher 60b that is capable of being elevated up and down is disposed below the third linear transporter 56c. Below the fourth transporter 56d, a lifter 58b that is capable of being elevated up and down is disposed.

As illustrated in FIGS. 2 and 3, a fifth linear transporter 56e, a sixth linear transporter 56f, and a seventh linear transporter 56g are disposed in order from the mounting unit 14 side on the second processing unit 40 side. In these components, below the fifth linear transporter 56e, a lifter 58c that is capable of being elevated up and down is disposed. In addition, below the sixth linear transporter 56f, a pusher 60c that is capable of being elevated up and down is disposed, and below the seventh linear transporter 56g, a pusher 60d that is capable of being elevated up and down is disposed.

Next, an example of processes of surface-treating (polishing) the substrate W using the substrate processing device (polishing device) 10 having such a configuration will be described.

First, odd-numbered substrates (a first substrate, a third substrate, and so on) taken out from one of the cassettes 12 mounted on the mounting unit 14 by the first transfer robot 54a are transferred through a route (transfer route) through the first reversing machine 52a→the first linear transporter 56a→the top ring 22a (the first polishing section 22 of the first processing unit 20)→the second linear transporter 56b→the top ring 24a (the second polishing section 24 of the first processing unit 20)→the third linear transporter 56c→the second transfer robot 54b→the second reversing machine 52b→the first cleaning machine 42a→the second cleaning machine 42b→the third cleaning machine 42c→the fourth cleaning machine 42d→the first transfer robot 54a, and returned to the original cassette 12.

In addition, the even-numbered substrates (a second substrate, a fourth substrate, and so on) taken out from one of the cassettes 12 mounted on the mounting unit 14 by the first transfer robot 54a are transferred through a route (transfer route) through the first reversing machine 52a→the fourth linear transporter 56d→the second transfer robot 54b→the fifth linear transporter 56e→the top ring 32a (the first polishing section 32 of the second processing unit 30)→the sixth linear transporter 56f→the top ring 34a (the second polishing section 34 of the second processing unit 30)→the seventh linear transporter 56g→the second transfer robot 54b→the second reversing machine 52b→the first cleaning machine 42a→the second cleaning machine 42b→the third cleaning machine 42c→the fourth cleaning machine 42d→the first transfer robot 54a, and returned to the original cassette 12.

Here, as described above, in the first polishing section 22 of the first processing unit 20 and the first polishing section 32 of the second processing unit 30, the copper film 7 and the seed layer 6 on the barrier layer 5 are polished and removed (first polishing), and in the second polishing section 24 of the first processing unit 20 and the second polishing section 34 of the second processing unit 30, the barrier layer 5 on the insulating film 2 and a part of the surface layer of the insulating film 2, as necessary, are polished and removed (second polishing). Then, the substrate after the second polishing is sequentially cleaned at the cleaning machines 42a to 42d, dried, and then returned to the cassette 12.

In the cleaning unit 40, the first substrate polished by the first processing unit 20 is cleaned at the first cleaning machine 42a, and then one substrate and the second substrate polished at the second processing unit 30 are simultaneously gripped by the transfer mechanism 44, the first substrate is transferred to the second cleaning machine 42b, the second substrate is transferred to the first cleaning machine 42a simultaneously, and the two substrates are simultaneously cleaned. Then, after the first substrate and the second substrate are cleaned, the first and second substrates and the third substrate polished at the first processing unit 20 are gripped by the transfer mechanism 44 simultaneously. The first substrate is transferred to the third cleaning machine 42c, the second substrate is transferred to the second cleaning machine 42b, and the third substrate is transferred to the first cleaning machine 42a simultaneously, and the three substrates are cleaned simultaneously. Such operations are repeated sequentially, and thus it is possible to handle processing at one cleaning unit 40 for the two processing units 20 and 30.

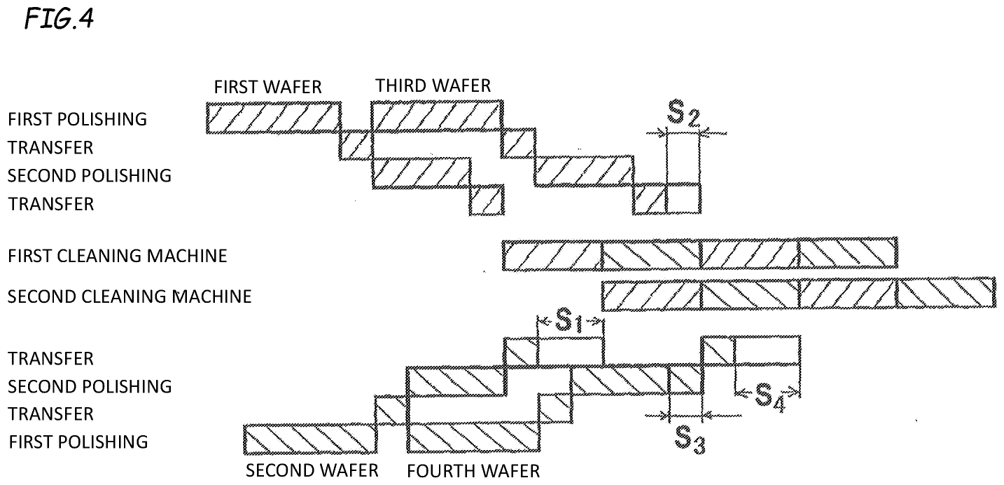

In this case, when the substrate processing device 10 is controlled by the control unit 70 so as to maximize the throughput, as illustrated in the time chart of FIG. 4, cleaning waiting time S₁ occurs in a period from the end of polishing the second substrate to cleaning at the first cleaning machine 42a. In addition, cleaning waiting time S₂ occurs in a period from polishing from the end of the third substrate to cleaning at the first cleaning machine 42a. Further, the fourth substrate has cleaning waiting times S3 and S4 in a period from polishing to cleaning at the first cleaning machine 42a. As described above, when cleaning waiting time occurs after the polishing is ended and before the cleaning is started, there is a concern about copper corrosion, for example, in the copper wire forming process.

In order to shorten the waiting time from the end of polishing to the start of cleaning, JP 5023146 B2 proposes that the average polishing time in the first polishing unit and the second polishing unit, the average transfer time in the transfer mechanism, and the average cleaning time in the cleaning unit are stored in advance, at the time of creating a time chart, the polishing start time in the first and second polishing units is determined based on the average polishing time, average transfer time, and average cleaning time such that the time from the end of polishing to the start of cleaning of the substrate is minimized.

However, according to the knowledge of the present inventors, the method of controlling processes according to a predetermined time chart has inconveniences below. That is, since the polishing time in the polishing unit is determined by detecting an end point, variations are present in the polishing time. This is because the end point is detected by different recipes for different products, and there is a correlation between the polishing time and the use time of a consumable member even in the same recipe. In addition, variations are present in the operating time of each unit due to mechanical variations. In addition, an interlock is present in the operation between specific units, and the units may not operate arbitrarily. In addition, a plurality of processing routes may coexist. In addition, a specific unit may fail to cause a suspension may occur. Therefore, for example, in the case in which the average transfer time is X seconds while the actual operation time is delayed by 0.5 seconds, the time chart may shift backwards, resulting in a large delay in the subsequent operation.

### First Embodiment

A machine learning device 80 according to a first embodiment described below is made in consideration of the above points, and enables appropriate determination of the timing of starting transfer of a substrate W and a transfer route of the substrate W according to a state from one time to another in the substrate processing device 10 (such that the number of processed substrates per unit time is large and the waiting time is short).

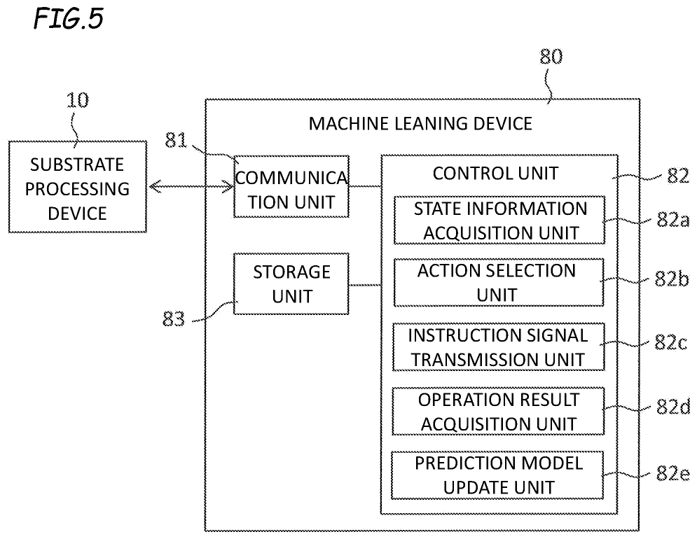

FIG. 5 is a block diagram that illustrates the configuration of the machine learning device 80 according to the first embodiment. At least a part of the machine learning device 80 is formed of one computer or a quantum computing system, or a plurality of computers or quantum computing systems connected to each other via a network.

As illustrated in FIG. 5, the machine learning device 80 has a communication unit 81, a control unit 82, and a storage unit 83. The units 81 to 83 are connected in a manner capable of communication through a bus or via a network.

Among these components, the communication unit 81 is a communication interface to the control unit 70 of the substrate processing device 10. The communication unit 81 may be connected to the control unit 70 of the substrate processing device 10 through cables or a wireless manner.

The storage unit 83 is a non-volatile data storage such as a flash memory. The storage unit 83 stores various items of data handled by the control unit 82.

As illustrated in FIG. 5, the control unit 82 has a state information acquisition unit 82a, an action selection unit 82b, an instruction signal transmission unit 82c, an operation result acquisition unit 82d, and a prediction model update unit 82e. These units may be implemented by a processor in the machine learning device 80 executing a predetermined program or may be mounted by hardware.

In the present embodiment, the control unit 82 performs reinforcement learning by repeating trial and error according to the state from time to time in the substrate processing device 10, on the timing of starting transfer of the substrate and the transfer route such that a waiting time that elapses until cleaning is started is shortened in the cleaning unit 40 in which there are a large number of substrates for processing per unit time and the surface-treated substrate waits for cleaning until cleaning is started. Although the algorithm of reinforcement learning is not particularly limited, for example, Q-learning, SARSA method, policy gradient method, Actor-Critic method, and the like can be used.

The state information acquisition unit 82a repeatedly acquires state information including the position of the substrate W in the substrate processing device 10 and the elapsed time of the substrate W located in each of the units 20, 30, and 40 in the unit from the control unit 70 of the substrate processing device 10 at predetermined time intervals (e.g., every 0.1 s).

The state information acquired by the state information acquisition unit 82a from the control unit 70 of the substrate processing device 10 may further include the use time of a consumable member used in the first processing unit 20 and the second processing unit 30. As a result of diligent investigation by the present inventors, it was found that there is a correlation of the processing time in the first processing unit 20 and the second processing unit 30 (e.g., the polishing time determined by end point detection) with the use time of a consumable member used in the first processing unit 20 and the second processing unit 30. Therefore, in the case in which the state information input to a prediction model 85, described later, includes the use time of a consumable member used in the first processing unit 20 and the second processing unit 30, it is possible to further improve the prediction accuracy by the prediction model 85. Examples of a consumable member may be one or two or more of polishing pads attached to the rotary tables 22b, 24b, 32b, and 34b, the retainer rings attached to the top rings 22a, 24a, 32a, and 34a to support the outer edge of the substrate W, and elastic films attached to the top rings 22a, 24a., 32a, and 34a to support the back surface of the substrate W.

The state information acquired by the state information acquisition unit 82a from the control unit 70 of the substrate processing device 10 may further include the recipe information of the treatment applied in advance to the substrate W housed in the cassette 12 (e.g., the film forming condition of the copper film 7 on the surface of the substrate W illustrated in FIG. 1B). As a result of diligent investigation by the present inventors, it was found that there is a correlation of the processing time in the first processing unit 20 and the second processing unit 30 (e.g., the polishing time determined by end point detection) with the recipe information of the treatment applied in advance in the substrate W housed in the cassette 12. Therefore, in the case in which the state information input to the prediction model 85, described later, includes the recipe information of the treatment applied in advance to the substrate W housed in the cassette 12, it is possible to improve the prediction accuracy by the prediction model 85.

The state information acquired by the state information acquisition unit 82a from the control unit 70 of the substrate processing device 10 may further include failure occurrence information or continuous operation time of the first processing unit 20 and the second processing unit 30. As a result of diligent investigation by the inventor of the present invention, when the operation interval between the first processing unit 20 and the second processing unit 30 is widened, the condition may change significantly by rewashing once due to retained water, it was found that there is a correlation of the processing time in the first processing unit 20 and the second processing unit 30 (e.g., the polishing time determined by end point detection) with the continuous operation time of the first processing unit 20 and the second processing unit 30. Therefore, in the case in which the state information input to the prediction model 85, described later, includes the continuous operation time of the first processing unit 20 and the second processing unit 30, it is possible to improve the prediction accuracy by the prediction model 85. In addition, even in the case in which the state information input to the prediction model 85, described later, includes the failure occurrence information of the first processing unit 20 and the second processing unit 30, it is possible to improve the prediction accuracy by the prediction model 85. This is because it is considered that in the case in which a failure occurs in one of the units, the transfer route can be changed to a unit that does not have a failure according to the situation and thus a large delay due to suspension can be avoided.

The state information acquired by the state information acquisition unit 82a from the control unit 70 of the substrate processing device 10 may further include the recipe information of surface treatment (polishing treatment) in the first processing unit 20 and the second processing unit 30. As a result of diligent investigation by the present inventors, the processing time in the first processing unit 20 and the second processing unit 30 (e.g., the polishing time determined by end point detection) is in correlation relationship with the recipe information of the surface treatment (polishing treatment) in the first processing unit 20 and the second processing unit 30. Therefore, in the case in which the state information input to the prediction model 85, described later, includes the recipe information of the surface treatment (polishing treatment) in the first processing unit 20 and the second processing unit 30, it is possible to improve the prediction accuracy by the prediction model 85.

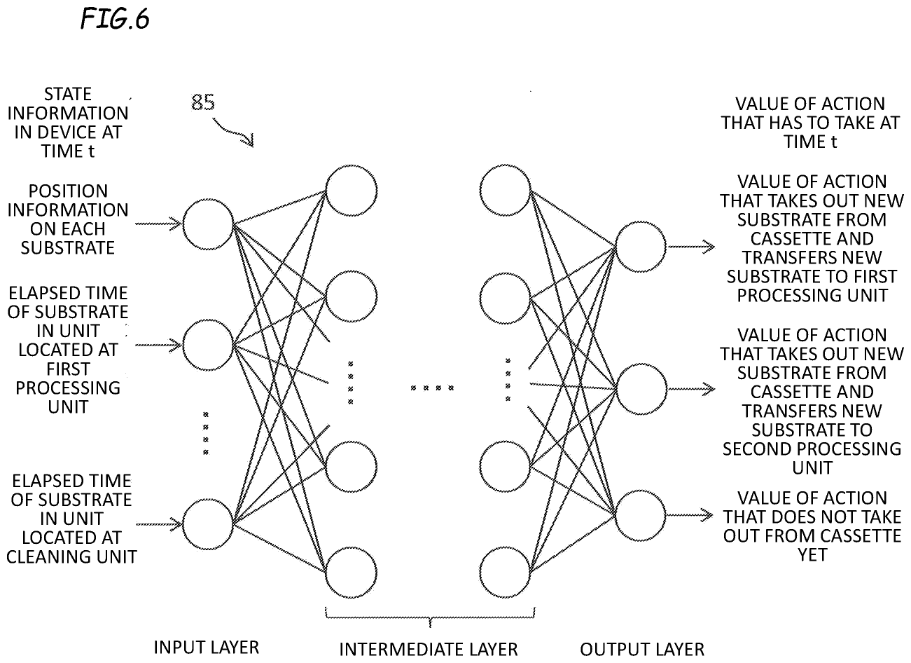

The action selection unit 82b has the prediction model 85 (see FIG. 6) that predicts a value (Q value in Q-learning) to perform an action, in a certain state sₜ, whether to take out a new substrate W from the cassette 12, and to which of the first processing unit 20 and the second processing unit 30 the new substrate W is transferred in the case of taking out the new substrate W.

FIG. 6 is a schematic diagram that explains an example of the configuration of the prediction model 85. In the example illustrated in FIG. 6, the prediction model 85 is a neural network system, including a hierarchical system having an input layer, one or more intermediate layers connected to the input layer, and an output layer connected to the intermediate layer, or a quantum neural network (QNN). In FIG. 6, although a feedforward neural network is illustrated as a hierarchical neural network, various types of neural networks such as a convolutional neural network (CNN) and a recurrent neural network (RNN) are usable. The prediction model 85 may include a neural network in which the intermediate layers are multi-layered in two layers or more, i.e., deep learning.

As illustrated in FIG. 6, in the prediction model 85, when state information acquired by the state information acquisition unit 82a is input to the input layer, the prediction model 85 predicts a value (Q value in Q learning) to performing an action whether or not to take out a new substrate W from the cassette 12 and to which one of the first processing unit 20 and the second processing unit 30 the new substrate W is transferred, and outputs the value from the output layer.

The action selection unit 82b may have a plurality of prediction models 85, and may estimate and output the value (Q value) of each action based on the combination of the prediction results by the plurality of prediction models 85 (i.e., ensemble learning) and out put the value.

The action selection unit 82b selects one action based on the prediction model 85 taking the state information acquired by the state information acquisition unit 82a as an input (i.e., an action that takes out a new substrate W from the cassette 12 to transfer the new substrate W to the first processing unit 20, an action that takes out a new substrate W from the cassette 12 to transfer the new substrate W to the second processing unit 20, and an action that does not take out a new substrate W from the cassette 12). As a selection method, for example, the action selection unit 82b may compare the value (Q value) of each action predicted by the prediction model 85 and select the action with the highest value (Q value) (greedy method), may randomly select actions at a predetermined probability ε or less, and may select an action with the highest value (Q value) (ε-greedy method) other than these methods.

The instruction signal transmission unit 82c transmits an instruction signal to the control unit 70 of the substrate processing device 10 so as to perform the action selected by the action selection unit 82b. The control unit 70 of the substrate processing device 10 acts according to the instruction signal received from the instruction signal transmission unit 82c, and then the state sₜ in the substrate processing device 10 transitions to the next state sₜ₊₁.

In the case in which the state st+1 after the transition is not in the terminal state (the state in which processing of the predetermined number of substrate is ended), the prediction model update unit 82e my update the prediction model 85 based on the maximum value (Q value) of the values of the actions output from the output layer in the case in which the state information of the state st+1 after transition acquired from state information acquisition unit 82a is input to the input layer of the prediction model 85 (e.g., update parameters (weights, thresholds, and the like) of each node in the neural network).

After finishing processing of a predetermined number of substrates (i.e., in the case in which the state sₜ₊₁ after the transition is the terminal state), the operation result acquisition unit 82d acquires an operation result including the number of processed substrates per unit time and the waiting time that elapses until cleaning of the surface-treated substrate is started in the cleaning unit 40 from the control unit 70 of the substrate processing device 10. Here, the “waiting time” may be the maximum value or the average value of the waiting time of each of the plurality of processed substrates.

After processing a predetermined number of substrate is ended (i.e., in the case in which the state sₜ₊₁ after the transition is the terminal state), the prediction model update unit 82e calculates a reward based on the operation result acquired by the operation result acquisition unit 82d such that the reward increases as the number of processed substrates is large and the waiting time is short, and updates the prediction model 85 based on the reward (e.g., updates parameters (weights, thresholds, and the like) of each node in the neural network).

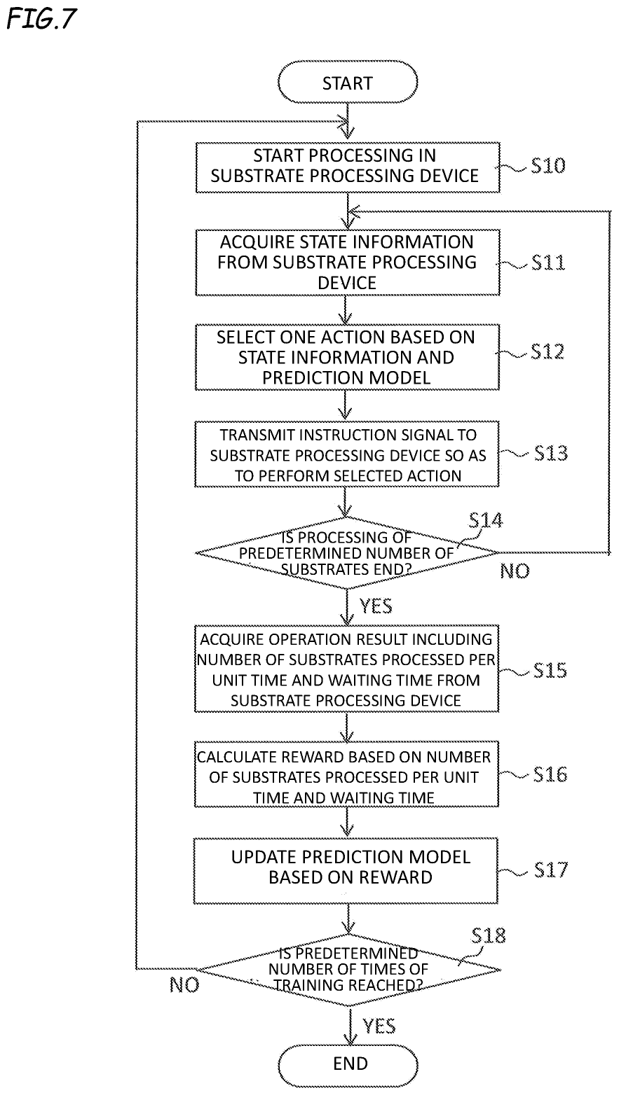

Next, an example of a machine learning method using the machine learning device 80 having such a configuration will be described. FIG. 7 is a flowchart that illustrates an example of a machine learning method.

As illustrated in FIG. 7, first, when one cycle of processing (i.e., processing of a predetermined number of substrates or a lot) is started in the substrate processing device 10, the control unit 82 of the machine learning device 80 receives a processing start notification from the control unit 70 of the substrate processing device 10 (Step S10).

Then, the state information acquisition unit 82a acquires state information including the position of the substrate W in the substrate processing device 10 and the elapsed time of the substrate W located in each of the units 20, 30, and 40 in the relevant unit from the control unit 70 of the substrate processing device 10 (Step S11).

The action selection unit 82b selects one action based on the prediction model 85 taking the state information acquired by the state information acquisition unit 82a as an input (i.e., an action that takes out a new substrate W from the cassette 12 to transfer the new substrate W to the first processing unit 20, an action that takes out a new substrate W from the cassette 12 to transfer the new substrate W to the second processing unit 20, and an action that does not take out a new substrate W from the cassette (Step S12).

Then, the instruction signal transmission unit 82c transmits an instruction signal to the control unit 70 of the substrate processing device 10 so as to perform the action selected by the action selection unit 82b (Step S13). The control unit 70 of the substrate processing device 10 acts according to the instruction signal received from the instruction signal transmission unit 82c, and then the state sₜ in the substrate processing device 10 transitions to the next state sₜ₊₁.

In the case in which the state sₜ₊₁ after the transition is not the terminal state (the state in which processing of a predetermined number of substrates is ended) (Step S14: NO), the process is repeated from Step S11. In this case, the prediction model update unit 82e may updates the prediction model 85 based on the maximum value (Q value) of the values of the actions output from the output layer in the case in which the state information of the state sₜ₊₁ after the transition acquired by the state information acquisition unit 82a is input to the input layer of the prediction model 85 (e.g., updates parameters (weights, thresholds, and the like) of each node in the neural network).

After processing of a predetermined number of substrates is ended (i.e., in the case in which the state sₜ₊₁ after the transition is the terminal state) (Step S14: YES), the operation result acquisition unit 82d acquires an operation result including the number of processed substrates per unit time and the waiting time that elapses until cleaning of the surface-treated substrate W is started in the cleaning unit 40 from the control unit 70 of the substrate processing device 10 (Step S15).

Subsequently, after processing of a predetermined number of substrates is ended (i.e., in the case in which the state sₜ₊₁ after the transition is the terminal state), the prediction model update unit 82e calculates a reward based on the operation result acquired by the operation result acquisition unit 82d such that the reward becomes larger as the number of processed substrates is larger and the waiting time is shorter (Step S16).

Then, the prediction model update unit 82e updates the prediction model 85 based on the calculated reward (e.g., updates the parameters (weights, thresholds, and the like) of each node in the neural network) (Step S17).

The control unit 82 of the machine learning device 80 determines whether a predetermined number of trainings (e.g., 10,000 times) is reached, and in the case in which the number of trainings is not reached (Step S18: NO), the control unit 82 repeats the process from Step S10. On the other hand, in the case in which a predetermined number of trainings is reached (Step S18: YES), the process is ended. As a result, a trained prediction model 85 (e.g., a tuned neural network system) is obtained.

The trained prediction model 85 (e.g., a tuned neural network system) created by the machine learning device 80 can be installed and utilized in the control unit 70 of the substrate processing device 10. The control unit 70 of the substrate processing device 10 in which the trained prediction model 85 is installed controls the operation of the transfer unit 50 such that the transfer unit 50 selects an action whether to take out a new substrate W from the cassette 12, and an action to which one of the first processing unit 20 and the second processing unit 3 the new substrate W is transferred in the case in which the new substrate W is taken out, taking, as an input, state information including the position of the substrate W in the substrate processing device 10 and the elapsed time of the substrates located in the units 20, 30 and 40 in the relevant unit based on the trained prediction model 85.

According to the first embodiment as described above, the machine learning device 80 performs try and error to select an action whether to take out a new substrate W from the cassette and an action to which one of the first processing unit 20 and the second processing unit 3 the new substrate W is transferred in the case in which the new substrate W is taken out, according to a state information including the position of the substrate W from time to time in the substrate processing device 10 and the elapsed time of the substrates located in the units 20, 30 and 40 in the relevant unit, based on the prediction model 85, after processing of a predetermined number of substrates is ended, a large reward is obtained, as the number of processed substrates per unit time is larger and the waiting time that elapses until cleaning of the surface-treated substrate is started is shorter, and the prediction model is updated based on the reward, and the processes are repeated, and thus machine learning (reinforcement learning) of the prediction model 85 is performed. As a result, with the use of the trained prediction model 85 created by the machine learning device 80, the timing of starting transfer of the substrate W and the transfer route can be set according to the state from one time to another in the substrate processing device 10. As a result, it becomes possible to make an appropriate decision (such that the number of processed substrates per unit time is large and the waiting time is short).

It should be noted that the machine learning device 80 according to the first embodiment described above has performed machine learning on the actual machine of the substrate processing device 10, but the machine learning is not limited to this, and the machine learning is performed on the simulator of the substrate processing device 10. In the initial stage of machine learning, machine learning may be performed on the simulator of the substrate processing device 10, and after the learning has progressed to some extent, machine learning may be performed on the actual machine of the substrate processing device 10.

### Second Embodiment

Next, the second embodiment will be described. In the conventional control method using a scheduler that manages the processes of transferring, processing (polishing), and cleaning the substrate according to a predetermined time chart, when control is performed as calculated time (without allowed time) based on average polishing time, average transfer time and average cleaning time, a delay definitely occurs and throughput is degraded due to variations in the polishing time, which are resulted from the polishing time in the polishing unit determined by end point detection. As a result, control is performed such that substrates stay in the device more or less and substrates arrive at a target place a little earlier, which avoids the occurrence of a delay. Conventionally, this allowed time is adjusted by human experience, and is uniformly determined regardless of the state from one time to another in the device.

In a machine learning device 180 according to a second embodiment, in the case in which a control unit 70 of a substrate processing device 10 controls the operations of a first processing unit 20, a second processing unit 30, a cleaning unit 40, and a transfer unit 50 according to a transfer rule to which a correspondence between the order of the substrates W to be taken out from the cassette 12 and to which one of the processing unit 20 and the second processing unit 30 a substrate W is to be transferred is defined (i.e., in the case in which a transfer route to which one of the processing unit 20 and the second processing unit 30 a substrate W newly taken out from a cassette 12 is transferred is predetermined), the timing of starting transfer of the substrate W can be appropriately determined according to a state from one time to another in the substrate processing device 10 (such that the number of processed substrates per unit time is large).

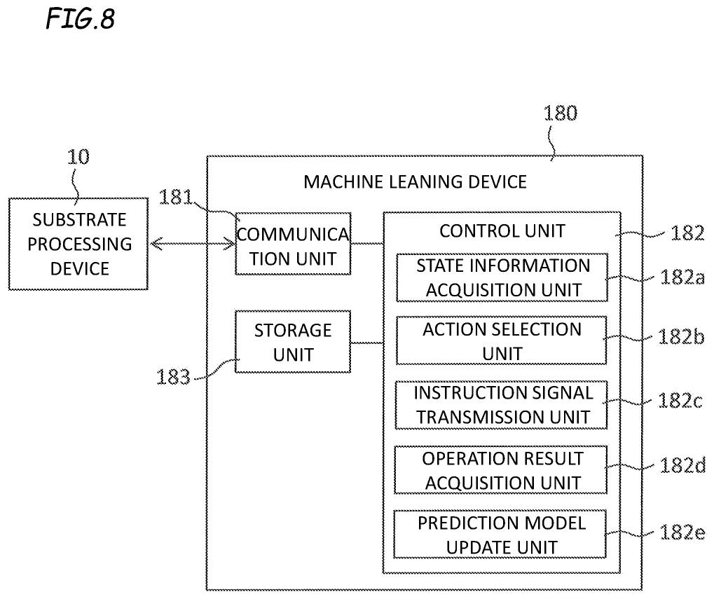

FIG. 8 is a block diagram that illustrates the configuration of the machine learning device 180 according to the second embodiment. At least a part of the machine learning device 180 is formed of one computer or a quantum computing system, or a plurality of computers or quantum computing systems connected to each other via a network.

As illustrated in FIG. 8, the machine learning device 180 has a communication unit 181, a control unit 182, and a storage unit 183. The units 181 to 183 are connected in a manner capable of communication through a bus or via a network.

Among these components, the communication unit 181 is a communication interface to the control unit 70 of the substrate processing device 10. The communication unit 181 may be connected to the control unit 70 of the substrate processing device 10 through cables or a wireless manner.

The storage unit 183 is a non-volatile data storage such as a flash memory. The storage unit 183 stores various items of data handled by the control unit 182.

As illustrated in FIG. 8, the control unit 182 has a state information acquisition unit 182a, an action selection unit 182b, an instruction signal transmission unit 182c, an operation result acquisition unit 182d, and a prediction model update unit 182e. These units may be implemented by a processor in the machine learning device 180 executing a predetermined program or may be mounted by hardware.

In the present embodiment, the control unit 182 performs reinforcement learning by repeating trial and error according to the state from time to time in the substrate processing device 10, on the timing of starting transfer of the substrate and the transfer route such that a waiting time that elapses until cleaning is started is shortened in the cleaning unit 40 in which there are a large number of substrates for processing per unit time and the surface-treated substrate waits for cleaning until cleaning is started. Although the algorithm of reinforcement learning is not particularly limited, for example, Q-learning, SARSA method, policy gradient method, Actor-Critic method, and the like can be used.

The state information acquisition unit 182a repeatedly acquires state information including the position of the substrate W in the substrate processing device 10 and the elapsed time of the substrate W located in each of the units 20, 30, and 40 from the control unit 70 in the substrate processing device 10 at predetermined time intervals (e.g., every 0.1 s).

The state information acquired by the state information acquisition unit 182a from the control unit 70 of the substrate processing device 10 may further include the use time of a consumable member used in the first processing unit 20 and the second processing unit 30. As a result of diligent investigation by the present inventors, it was found that there is a correlation of the processing time in the first processing unit 20 and the second processing unit 30 (e.g., the polishing time determined by end point detection) with the use time of a consumable member used in the first processing unit 20 and the second processing unit 30. Therefore, in the case in which the state information input to a prediction model 185, which will be described later, includes use time of a consumable member used in the first processing unit 20 and the second processing unit 30, the prediction accuracy by the prediction model 185 can be further improved. Examples of a consumable member may be one or two or more of polishing pads attached to the rotary tables 22b, 24b, 32b, and 34b, the retainer rings attached to the top rings 22a, 24a, 32a, and 34a to support the outer edge of the substrate W, and elastic films attached to the top rings 22a, 24a., 32a, and 34a to support the back surface of the substrate W.

The state information acquired by the state information acquisition unit 182a from the control unit 70 of the substrate processing device 10 may further include the recipe information of the treatment applied in advance to the substrate W housed in the cassette 12 (e.g., the film forming condition of the copper film 7 on the surface of the substrate W illustrated in FIG. 1B). As a result of diligent investigation by the present inventors, it was found that there is a correlation of the processing time in the first processing unit 20 and the second processing unit 30 (e.g., the polishing time determined by end point detection) with the recipe information of the treatment applied in advance in the substrate W housed in the cassette 12. Therefore, in the case in which the state information input to the prediction model 185, described later, includes the recipe information of the treatment applied in advance to the substrate W housed in the cassette 12, it is possible to improve the prediction accuracy by the prediction model 185.

The state information acquired by the state information acquisition unit 182a from the control unit 70 of the substrate processing device 10 may further include continuous operation time of the first processing unit 20 and the second processing unit 30. As a result of diligent investigation by the inventor of the present invention, when the operation interval between the first processing unit 20 and the second processing unit 30 is widened, the condition may change significantly by rewashing once due to retained water, it was found that there is a correlation of the processing time in the first processing unit 20 and the second processing unit 30 (e.g., the polishing time determined by end point detection) with the continuous operation time of the first processing unit 20 and the second processing unit 30. Therefore, in the case in which the state information input to the prediction model 85, described later, includes the continuous operation time of the first processing unit 20 and the second processing unit 30, it is possible to improve the prediction accuracy by the prediction model 85.

The state information acquired by the state information acquisition unit 182a from the control unit 70 of the substrate processing device 10 may further include the recipe information of surface treatment (polishing treatment) in the first processing unit 20 and the second processing unit 30. As a result of diligent investigation by the present inventors, the processing time in the first processing unit 20 and the second processing unit 30 (e.g., the polishing time determined by end point detection) is in correlation relationship with the recipe information of the surface treatment (polishing treatment) in the first processing unit 20 and the second processing unit 30. Therefore, in the case in which the state information input to the prediction model 185, described later, includes the recipe information of the surface treatment (polishing treatment) in the first processing unit 20 and the second processing unit 30, it is possible to improve the prediction accuracy by the prediction model 185.

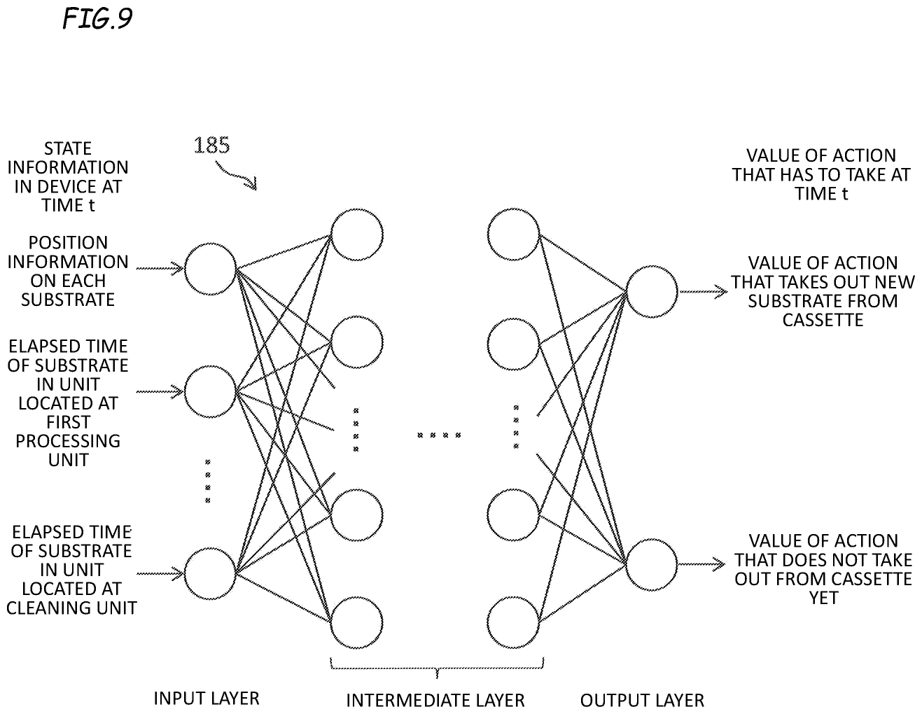

The action selection unit 182b has a prediction model 185 (see FIG. 9) that predicts the value (Q value in Q learning) to perform an action of whether to take out a new substrate W from the cassette 12 in a certain state sₜ.

FIG. 9 is a schematic diagram that explains an example of the configuration of the prediction model 185. In the example illustrated in FIG. 9, the prediction model 185 is a neural network system, including a hierarchical system having an input layer, one or more intermediate layers connected to the input layer, and an output layer connected to the intermediate layer or a quantum neural network (QNN). In FIG. 9, although a feedforward neural network is illustrated as a hierarchical neural network, various types of neural networks such as a convolutional neural network (CNN) and a recurrent neural network (RNN) are usable. The prediction mode1185 may include a neural network in which the intermediate layers are multi-layered in two layers or more, i.e., deep learning.

As illustrated in FIG. 9, in the prediction model 185, when state information acquired by the state information acquisition unit 182a is input to the input layer, the prediction model 185 predicts a value (Q value in Q learning) to perform an action to take out a new substrate W from the cassette 12 and to which one of the first processing unit 20 and the second processing unit 30 the new substrate W is transferred when the new substrate W is taken out, and outputs the value from the output layer.

The action selection unit 182b may have a plurality of prediction models 185, and may estimate and output the value (Q value) of each action based on the combination of the prediction results by the plurality of prediction models 185 (i.e., ensemble learning).

The action selection unit 182b takes the state information acquired by the state information acquisition unit 182a as an input and selects one action based on the prediction model 185 (i.e., an action that takes out a new substrate W from the cassette 12 and an action that does not take out the new substrate W from the cassette 12). As a selection method, for example, the action selection unit 182b may compare the value (Q value) of each action predicted by the prediction model 185 and select the action with the highest value (Q value) (greedy method), may randomly select actions at a predetermined probability ε or less, and may select an action with the highest value (Q value) (ε-greedy method) other than these methods.

The instruction signal transmission unit 182c transmits an instruction signal to the control unit 70 of the substrate processing device 10 so as to perform the action selected by the action selection unit 182b. The control unit 70 of the substrate processing device 10 acts according to the instruction signal received from the instruction signal transmission unit 182c, and then the state sₜ in the substrate processing device 10 transitions to the next state sₜ₊₁.

In the case in which the state sₜ₊₁ after the transition is not in the terminal state (the state in which processing of the predetermined number of substrate is ended), the prediction model update unit 182e my update the prediction model 185 based on the maximum value (Q value) of the values of the actions output from the output layer in the case in which the state information of the state sₜ₊₁ after transition acquired from the state information acquisition units 182a is input to the input layer of the prediction model 185 (e.g., update parameters (weights, thresholds, and the like) of each node in the neural network).

After processing a predetermined number of substrate is ended (i.e., in the case in which the state sₜ₊₁ after the transition is the terminal state), the operation result acquisition unit 182d acquires the operation result including the number of processed substrates per unit time from the control unit 70 of the substrate processing device 10.

After processing a predetermined number of substrate is ended (i.e., in the case in which the state sₜ₊₁ after the transition is the terminal state), the prediction model update unit 182e calculates a reward based on the operation result acquired by the operation result acquisition unit 182d such that the reward increases as the number of processed substrates is large, and updates the prediction model 185 based on the reward (e.g., updates parameters (weights, thresholds, and the like) of each node in the neural network).

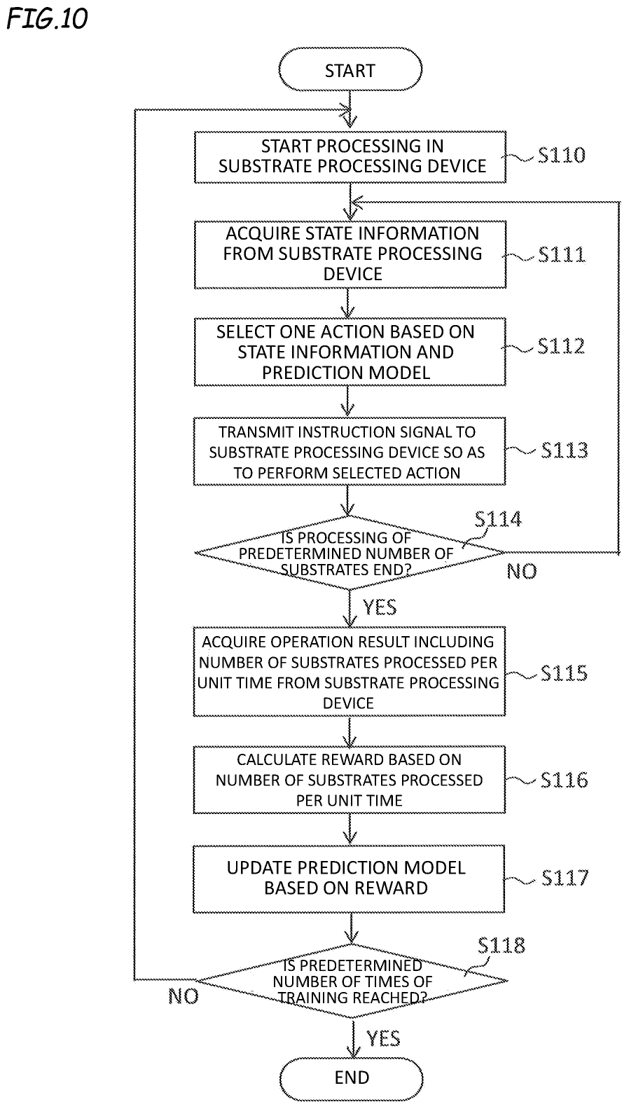

Next, an example of a machine learning method using the machine learning device 180 having such a configuration will be described. FIG. 10 is a flowchart that illustrates an example of a machine learning method.

As illustrated in FIG. 10, first, when one cycle of processing (i.e., processing of a predetermined number of substrates or a lot) is started in the substrate processing device 10, the control unit 182 of the machine learning device 180 receives a processing start notification from the control unit 70 of the substrate processing device 10 (Step S110).

Then, the state information acquisition unit 182a acquires state information including the position of the substrate W in the substrate processing device 10 and the elapsed time of the substrate W located in each of the units 20, 30, and 40 in the unit from the control unit 70 of substrate processing device 10 (Step S111).

Subsequently, the action selection unit 182b takes the state information acquired by the state information acquisition unit 182a as an input and selects one action based on the prediction model 185 (i.e., an action that takes out a new substrate W from the cassette 12 and an action that does not take out the new substrate W from the cassette (Step S112).

Then, the instruction signal transmission unit 182c transmits an instruction signal to the control unit 70 of the substrate processing device 10 so as to perform the action selected by the action selection unit 182b (Step S113). The control unit 70 of the substrate processing device 10 acts according to the instruction signal received from the instruction signal transmission unit 82c, and then the state sₜ in the substrate processing device 10 transitions to the next state sₜ₊₁.

In the case in which the state sₜ₊₁ after the transition is not the terminal state (the state in which processing of a predetermined number of substrates is ended) (Step S114: NO), the process is repeated from Step S111. In this case, the prediction model update unit 182e may updates the prediction model 185 based on the maximum value (Q value) of the values of the actions output from the output layer in the case in which the state information of the state sₜ₊₁ after the transition acquired by the state information acquisition unit 182a is input to the input layer of the prediction model 185 (e.g., updates parameters (weights, thresholds, and the like) of each node in the neural network).

After processing a predetermined number of substrate is ended (i.e., in the case in which the state sₜ₊₁ after the transition is the terminal state) (Step S114: YES), the operation result acquisition unit 182d acquires the operation result including the number of processing substrates per unit time from the control unit 70 of the substrate processing device 10 (Step S115).

Subsequently, after processing of a predetermined number of substrates is ended (i.e., in the case in which the state sₜ₊₁ after the transition is the terminal state), the prediction model update unit 182e calculates a reward based on the operation result acquired by the operation result acquisition unit 182d such that the number of processed substrates is larger (Step S116).

Then, the prediction model update unit 182e updates the prediction model 185 based on the calculated reward (e.g., updates the parameters (weights, thresholds, and the like) of each node in the neural network) (Step S117).

After that, the control unit 182 of the machine learning device 180 determines whether a predetermined number of trainings (e.g., 10,000 times) is reached, and in the case in which the number of trainings is not reached (Step S118: NO), the control unit 182 repeats the process from Step S110. On the other hand, in the case in which a predetermined number of trainings is reached (Step S118: YES), the process is ended. As a result, a trained prediction model 185 (e.g., a tuned neural network system) is obtained.

The trained prediction model 185 (e.g., a tuned neural network system) created by the machine learning device 180 can be installed and utilized in the control unit 70 of the substrate processing device 10. The control unit 70 of the substrate processing device 10 in which the trained prediction model 185 is installed controls the operations of the first processing unit 20, the second processing unit 30, the cleaning unit 40, and the transfer unit 50 according to a transfer rule to which a correspondence between the order of the substrates W to be taken out from the cassette 12 and to which one of the processing unit 20 and the second processing unit 30 a substrate W is to be transferred is defined, takes, as an input, state information including the position of the substrate W in the substrate processing device 10 and the elapsed time of the substrates located in the units 20, 30 and 40 in the relevant unit, selects an action whether to take out a new substrate W from the cassette 12 based on the trained prediction model 185, and control the operation of the transfer unit 50 to perform the selected action.

According to the second embodiment as described above, the machine learning device 180 performs try and error to select an action whether to take out a new substrate W from the cassette taking, according to a state information including the position of the substrate W in the substrate processing device 10 and the elapsed time of the substrates located in the units 20, 30 and 40 in the relevant unit according to the state information including the position of the substrate W from one time to another in the substrate processing device 10 and an elapsed time of substrates W located in the units 20, 30, and 40 in a relevant unit based on the prediction model 185, after processing of a predetermined number of substrates is ended, a large reward is obtained as the number of processed substrates per unit time is larger, and the prediction model is updated based on the reward, and the processes are repeated, and thus machine learning (reinforcement learning) of the prediction model 185 is performed. As a result, with the use of the trained prediction model 185 created by such a machine learning device 180, it is possible to appropriately determine the timing of starting transfer of the substrate W according to the state from one time to another in the substrate processing device 10 (such that the number of processed substrates per hour is large).

It should be noted that the machine learning device 180 according to the second embodiment described above performs machine learning on the actual machine of the substrate processing device 10. However, the machine learning is not limited to this, and the machine learning may be performed on the simulator of the substrate processing device 10. Alternatively, in the initial stage of machine learning, machine learning may be performed on the simulator of the substrate processing device 10, and after the learning progresses to some extent, machine learning may be performed on the actual machine of the substrate processing device 10.

### Third Embodiment

Next, a third embodiment will be described. In the conventional control method using a scheduler that manages the process of transferring, processing (polishing) and cleaning the substrate according to a predetermined time chart, when control is performed as calculated time based on average polishing time, average transfer time and average cleaning time, a delay occurs and throughput is degraded due to there is a correlation and the like between the polishing time and the use time of a consumable member even the same recipe.

In a machine learning device 280 according to the third embodiment, in the case in which a control unit 70 of a substrate processing device 10 controls the operations of a first processing unit 20, a second processing unit 30, a cleaning unit 40, and a transfer unit 50 according to transfer rules in which a correspondence between the order of the substrates W taken out from the cassette 12, to which one of the processing unit 20 and the second processing unit 30 a substrate W is transferred, and transfer start time is defined (i.e., the timing of taking out a new substrate W from a cassette 12 and a transfer route to which one of the processing unit 20 and the second processing unit 30 the substrate W newly taken out from the cassette 12 is transferred is predetermined), it is possible to accurately predict surface treatment time in the processing unit in consideration of the recipe information of surface treatment (polishing) in the processing unit, the use time of a consumable member used in the processing unit, and the continuous operation time of the processing unit as well as substrate information, and thus it is possible to accurately determine the timing of starting transfer of a substrate based on the predicted surface treatment time at the time of creating a time chart (transfer rule).

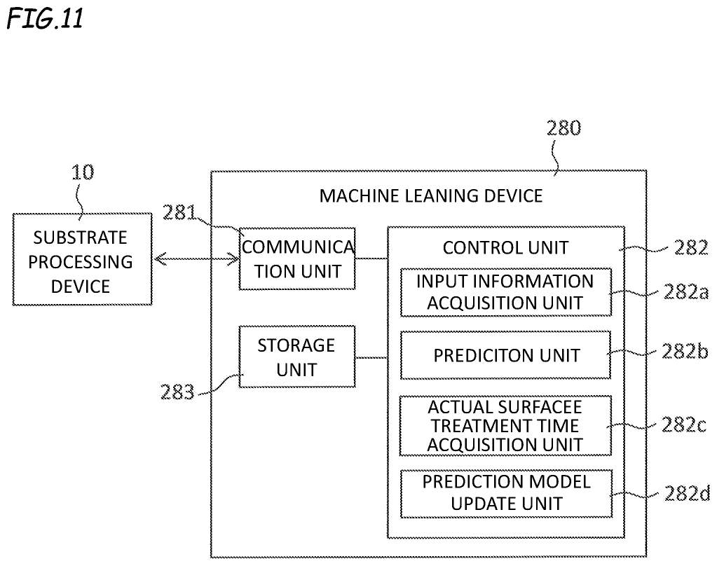

FIG. 11 is a block diagram that illustrates a configuration of the machine learning device 280 according to the third embodiment. At least a part of the machine learning device 280 is formed of one computer or a quantum computing system, or a plurality of computers or quantum computing systems connected to each other via a network.

As illustrated in FIG. 11, the machine learning device 280 has a communication unit 281, a control unit 282, and a storage unit 283. The units 281 to 283 are connected in a manner capable of communication through a bus or via a network.

Among these components, the communication unit 281 is a communication interface to the control unit 70 of the substrate processing device 10. The communication unit 281 may be connected to the control unit 70 of the substrate processing device 10 through cables or a wireless manner.

The storage unit 283 is a non-volatile data storage such as a flash memory. The storage unit 283 stores various items of data handled by the control unit 282.

As illustrated in FIG. 11, the control unit 282 has an input information acquisition unit 282a, a prediction unit 282b, an actual surface time acquisition unit 282c, and a prediction model update unit 282d. These units may be implemented by a processor in the machine learning device 280 executing a predetermined program or may be mounted by hardware.

In the present embodiment, the control unit 282 performs machine learning (supervised learning) the relationship between the recipe information of the surface treatment in the first processing unit 20 (or the second processing unit 30) that surface-treats the substrate W, substrate information, the use time of a consumable member used in the first processing unit 20 (or the second processing unit 30), the continuous operation time of the first processing unit 20 (or the second processing unit 30), and actual surface treatment time in the first processing unit 20 (or the second processing unit 30).

The input information acquisition unit 282a acquires the recipe information of the surface treatment in the first processing unit 20 (or the second processing unit 30), substrate information (e.g., the film forming condition of the copper film 7 on the surface of the substrate W illustrated in FIG. 1B), the use time of a consumable member used in the first processing unit 20 (or the second processing unit 30), and the continuous operation time of the first processing unit 20 (or the second processing unit 30) as input information from the control unit 70 of the substrate processing device 10. Examples of a consumable member may be one or two or more of polishing pads attached to the rotary tables 22b, 24b, 32b, and 34b, the retainer rings attached to the top rings 22a, 24a, 32a, and 34a to support the outer edge of the substrate W, and elastic films attached to the top rings 22a, 24a., 32a, and 34a to support the back surface of the substrate W.

As a result of diligent investigation by the present inventors, it was found that the processing time in the first processing unit 20 (or the second processing unit 30) (e.g., the polishing time determined by end point detection) has a correlation with the use time of a consumable members used in the first processing unit 20 (or the second processing unit 30). In addition, as a result of diligent investigation by the present inventors, it was found that when the operation interval of the first processing unit 20 (or the second processing unit 30) is widened, water may stay and the condition may be largely changed due to recleaning once, the processing time in the first processing unit 20 (or the second processing unit 30) (e.g., the polishing time determined by end point detection) has a correlation with the continuous operation of the first processing unit 20 (or the second processing unit 30). Therefore, the input information input to a prediction model 285, which will be described later, includes use time of a consumable member and the continuous operation time of the processing unit, such that the prediction accuracy by the prediction model 285 can be significantly improved.

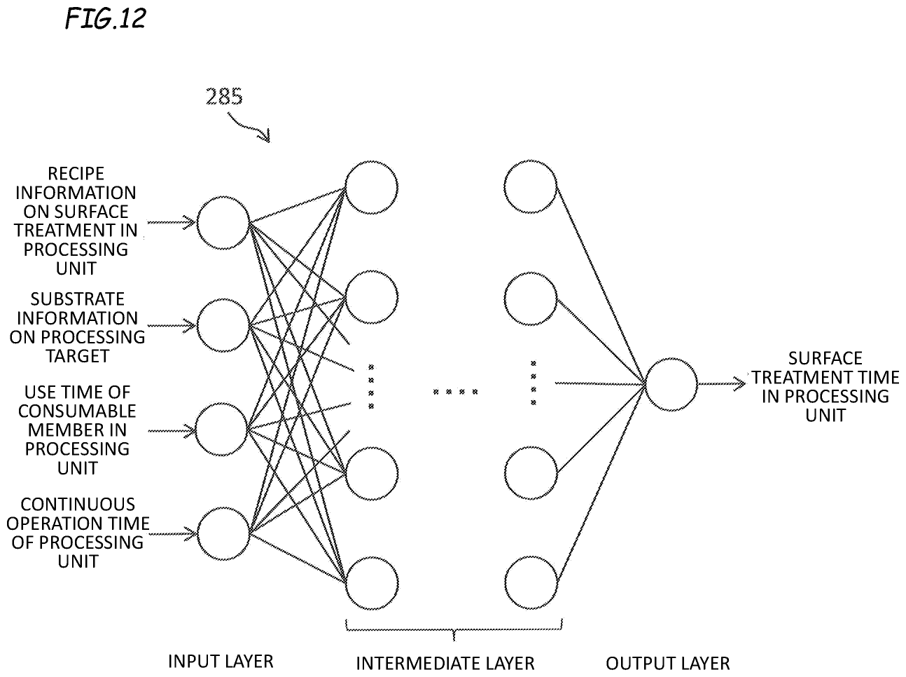

The prediction unit 282b has he prediction model 285 (see FIG. 12) that predicts the surface treatment time in the first processing unit 20 (or the second processing unit 30) based on the recipe information of the surface treatment in the first processing unit 20 (or the second processing unit 30), substrate information, the use time of a consumable member in the first processing unit 20 (or the second processing unit 30) and the continuous operation time of the first processing unit 20 (or the second processing unit 30).

FIG. 12 is a schematic diagram that explains an example of the configuration of the prediction model 285. In the example illustrated in FIG. 12, the prediction model 285 is a neural network system, including a hierarchical system having an input layer, one or more intermediate layers connected to the input layer, and an output layer connected to the intermediate layer or a quantum neural network (QNN). In FIG. 12, although a feedforward neural network is illustrated as a hierarchical neural network, various types of neural networks such as a convolutional neural network (CNN) and a recurrent neural network (RNN) are usable. The prediction model285 may include a neural network in which the intermediate layers are multi-layered in two layers or more, i.e., deep learning.

As illustrated in FIG. 12, when input information acquired by the input information acquisition unit 282a (i.e., recipe information of surface treatment in the first processing unit 20 (or second processing unit 30)), substrate information, the use time of a consumable member used in the first processing unit 20 (or the second processing unit 30), and the continuous operation time of the first processing unit 20 (or the second processing unit 30) are input to the input layer, the prediction model 285 predicts surface treatment time in the first processing unit 20 (or the second processing unit 30), and outputs the surface treatment time from the output layer.

The actual surface treatment time acquisition unit 282c acquires the actual surface treatment time in the first processing unit 20 (or the second processing unit 30) from the control unit 70 of the substrate processing device 10.

The prediction model update unit 282d compares the actual surface treatment time acquired by the actual surface treatment time acquisition unit 282c with the surface treatment time predicted by the prediction unit 292b, and updates the prediction model 285 according to the error (e.g., updates parameters (weights, thresholds, and the like) of each node in the neural network).

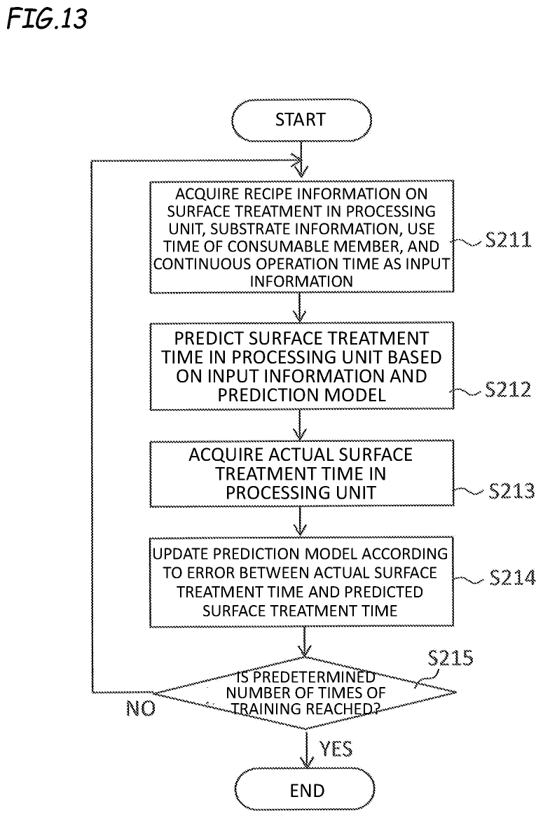

Next, an example of a machine learning method using the machine learning device 280 having such a configuration will be described. FIG. 13 is a flowchart that illustrates an example of the machine learning method.

As illustrated in FIG. 13, first, the input information acquisition unit 282a acquires the recipe information of the surface treatment in the first processing unit 20 (or the second processing unit 30), substrate information (e.g., the film forming condition of the copper film 7 on the surface of the substrate W illustrated in FIG. 1B), the use time of a consumable member used in the first processing unit 20 (or the second processing unit 30), and the continuous operation time of the first processing unit 20 (or the second processing unit 30) as input information from the control unit 70 of the substrate processing device 10 (Step S211).

Subsequently, the prediction unit 282b takes, as an input, the input information acquired by the input information acquisition unit 282a i.e., the recipe information of the surface treatment in the first processing unit 20 (or the second processing unit 30), the substrate information, the use time of a consumable member used in the first processing unit 20 (or the second processing unit 30), and the continuous operation time of the first processing unit 20 (or the second processing unit 30), predicts surface treatment time in the first processing unit 20 (or the second processing unit 30) and outputs the surface treatment time based on the prediction model 285 (Step S212).

Subsequently, the actual surface treatment time acquisition unit 282c acquires the actual surface treatment time in the first processing unit 20 (or the second processing unit 30) from the control unit 70 of the substrate processing device 10 (Step S213).

Then, the prediction model update unit 282d compares the actual surface treatment time acquired by the actual surface treatment time acquisition unit 282c with the surface treatment time predicted by the prediction unit 292b, and updates the prediction model 285 according to the error (e.g., updates parameters (weights, thresholds, and the like) of each node in the neural network) (Step S214).

After that, the control unit 282 of the machine learning device 280 determines whether a predetermined number of trainings (e.g., 10,000 times) is reached, and in the case in which the number of trainings is not reached (Step S215: NO), the control unit 282 repeats the process from Step S211. On the other hand, in the case in which a predetermined number of trainings is reached (Step S215: YES), the process is ended. As a result, a trained prediction model 285 (e.g., a tuned neural network system) is obtained.

The trained prediction model 285 (e.g., a tuned neural network system) created by the machine learning device 280 can be installed and utilized in the control unit 70 of the substrate processing device 10. The control unit 70 of the substrate processing device 10 in which the trained prediction model 285 is installed controls the operations of the first processing unit 20, the second processing unit 30, the cleaning unit 40, and the transfer unit 50 according to the transfer rule defining a correspondence between the order of the substrates W taken out from the cassette 12, to which one of the processing unit 20 and the second processing unit 30 a substrate W is transferred, and transfer start time, predicts surface treatment time in the first processing unit 20 (or the second processing unit 30), taking, as an input, the recipe information of surface treatment in the first processing unit 20 (or the second processing unit 30), substrate information (e.g., the film forming conditions of the copper film 7 on the surface of the substrate w illustrated in FIG. 1B), the use time of a consumable member used in the surface treatment time in 20 (or the second processing unit 30), and the continuous operation time of the first processing unit 20 (or the second processing unit 30) based on the trained prediction model 285, and determines the timing of starting transfer of the substrate based on the predicted surface treatment time at the time of creating the time chart (transfer rule). It should be noted that as a specific method of determining the timing of starting transfer of the substrate based on the predicted surface treatment time when creating the time chart, for example, the method proposed in JP 5023146 B2 can be used.

According to the third embodiment as described above, the machine learning device 280 performs machine learning (supervised learning) of the prediction model 285 using, as teacher data, the correspondence between the recipe information of the surface treatment in the first processing unit 20 (or the second processing unit 30), the substrate information, the use time of a consumable member used in 20 (or the second processing unit 30), the continuous operation time of the first processing unit 20 (or the second processing unit 30), and the actual surface treatment time in the first processing unit 20 (or the second processing unit 30). As a result, with the use of the trained prediction model 285 created by such a machine learning device 280, also in consideration of the recipe information of the surface treatment in the first processing unit 20 (or the second processing unit 30) and the substrate information as well as the use time of the a consumable member used in the first processing unit 20 (or the second processing unit 30) and the continuous operation time of the first processing unit 20 (or the second processing unit 30), it is possible to accurately predict the surface treatment time in the first processing unit 20 (or the second processing unit 30), and thus it is possible to accurately determine the timing of the starting transfer based on the predicted surface treatment time at the time of creating the time chart.

It should be noted that the machine learning devicees 80, 180, and 280 according to the foregoing embodiments may be configured of one computer or a quantum computing system, or a plurality of computers or quantum computing systems connected to each other via a network. However, a non-transitory, computer-readable recording medium on which a program that implements the machine learning devicees 80, 180, and 280 is recorded is also a protection target of the present application.

As described above, although the embodiments and the exemplary modifications are described with examples, the scope of the present invention is not limited to the embodiments and the exemplary modifications, and it is possible to modify and alter the present invention according the applications within the scope described in claims. It is possible to appropriately combine the embodiments and the exemplary modifications in the scope with no contradiction in the content of the processes.

1. A machine learning device that performs machine learning to a substrate processing device having
a mounting unit on which a cassette that houses a plurality of substrates is mounted,
a first processing unit and a second processing unit that surface-treat a substrate,
a cleaning unit that cleans a substrate after surface treatment,
a transfer unit that transfers a substrate between the mounting unit, the first processing unit and the second processing unit, and the cleaning unit, and
a control unit that controls operations of the first processing unit, the second processing unit, the cleaning unit, and the transfer unit,
or to a simulator of the substrate processing device, the machine learning device comprising:
a state information acquisition unit that acquires state information including a position of a substrate in the substrate processing device and an elapsed time of a substrate located in each unit in a relevant unit;
an action selection unit having a prediction model that predicts a value, in a certain state, to performing an action whether to take out a new substrate from the cassette and a value to which one of the first processing unit and the second processing unit a new substrate is transferred when a new substrate is taken out, the action selection unit selecting one action based on the prediction model taking, as an input, the state information acquired by the state information acquisition unit;
an instruction signal transmission unit that transmits an instruction signal to the control unit so as to perform the action selected by the action selection unit;
an operation result acquisition unit that acquires, after finishing processing a predetermined number of substrates, an operation result including a predetermined number of substrates processed per unit time and a waiting time that elapses until cleaning of a substrate after surface treatment is started in the cleaning unit; and
a prediction model update unit that calculates a reward based on an operation result acquired by the operation result acquisition unit such that a reward increases as the number of substrates processed increases and the waiting time becomes shorter and that updates the prediction model based on the reward.

2. The machine learning device according to claim 1, wherein
the first processing unit and the second processing unit are polishing units that polish a substrate.

3. The machine learning device according to claim 1, wherein
the state information further includes use time of a consumable member used in the first processing unit and the second processing unit.

4. The machine learning device according to claim 3, wherein
the first processing unit and the second processing unit are polishing units that polish a substrate, and
the consumable member is one or two or more of a polishing pad attached to a rotary table, a retainer ring attached to a top ring, the retainer ring supporting an outer edge of the substrate, and an elastic film attached to the top ring, the elastic film supporting a back surface of the substrate.

5. The machine learning device according to claim 1, wherein
the state information further includes recipe information on treatment applied in advance to the substrate housed in the cassette.

6. The machine learning device according to claim 1, wherein
the state information further includes failure occurrence information or continuous operation time of the first processing unit and the second processing unit.

7. The machine learning device according to claim 1, wherein
the state information further includes recipe information on surface treatment in the first processing unit and the second processing unit.

8. A substrate processing device comprising:
a mounting unit on which a cassette that houses a plurality of substrates is mounted;
a first processing unit and a second processing unit that surface-treat a substrate;
a cleaning unit that cleans a substrate after surface treatment;
a transfer unit that transfers a substrate between the mounting unit, the first processing unit and the second processing unit, and the cleaning unit; and
a control unit that controls operations of the first processing unit, the second processing unit, the cleaning unit, and the transfer unit, wherein
the control unit has a trained model created by the machine learning device according to claim 1, the control unit selects an action whether to take out a new substrate from the cassette and to which one of the first processing unit and the second processing unit the new substrate is transferred when taking out the new substrate from the cassette, taking, as an input, state information including a position of a substrate in the substrate processing device and an elapsed time of a substrate in the units in a relevant unit based on the trained model, and the control unit controls an operation of the transfer unit so as to perform the selected action.

9. A trained model created by performing machine leaning to a substrate processing device having
a mounting unit on which a cassette that houses a plurality of substrates is mounted,
a first processing unit and a second processing unit that surface-treat a substrate,
a cleaning unit that cleans a substrate after surface treatment,
a transfer unit that transfers a substrate between the mounting unit, the first processing unit and the second processing unit, and the cleaning unit, and
a control unit that controls operations of the first processing unit, the second processing unit, the cleaning unit, and the transfer unit,
or to a simulator of the substrate processing device, the trained model comprising:
an input layer, one or more intermediate layers connected to the input layer, and an output layer connected to the intermediate layer, wherein
the trained model is subjected to reinforcement learning on timing of starting transfer of a substrate and a transfer route of the substrate in which
state information including a position of a substrate in the substrate processing device and an elapsed time of a substrate located in each unit in the relevant unit is acquired, the acquired state information is input to the input layer, based on an input then output from the output layer, the value to performing an action whether to take out a new substrate from the cassette, and to which one of the first processing unit and the second processing unit a new substrate is transferred when a new substrate is taken out, one action is selected, an operation of the transfer unit is controlled so as to perform the selected action, after processing of a predetermined number of substrates is ended, an operation result including a number of substrates processed per unit time and a waiting time that elapses until cleaning of a surface-treated substrate is started in the cleaning unit is acquired, a reward is calculated based on the acquired operation result such that the reward increases as the number of substrates processed is large and the waiting time is short, a process of updating a parameter of each node is repeated based on the reward, such that the number of substrates processed is large and the waiting time is short, and
the trained model causes a computer to function to predict, upon inputting state information including a position of a substrate in the substrate processing device and an elapsed time of a substrate located in each unit in a relevant unit to the input layer, a value to performing an action whether to take out a new substrate from the cassette, and to which one of the first processing unit and the second processing unit a new substrate is transferred when a new substrate is taken out and output the value from the output layer.

10. A machine learning method executed by a computer to a substrate processing device having
a mounting unit on which a cassette that houses a plurality of substrates is mounted,
a first processing unit and a second processing unit that surface-treat a substrate,
a cleaning unit that cleans a substrate after surface treatment,
a transfer unit that transfers a substrate between the mounting unit, the first processing unit and the second processing unit, and the cleaning unit, and
a control unit that controls operations of the first processing unit, the second processing unit, the cleaning unit, and the transfer unit,
or to a simulator of the substrate processing device, the machine learning method comprising:
a state information acquisition step of acquiring state information including a position of a substrate in the substrate processing device and an elapsed time of a substrates located in each unit in a relevant unit;
an action selecting step of selecting one action based on a prediction model that predicts a value, in a certain state, to performing an action whether to take out a new substrate from the cassette and a value to which one of the first processing unit and the second processing unit the new substrate is transferred when the new substrate is taken out, taking, as an input, the state information acquired by the state information acquisition step;
an instruction signal transmission step of transmitting an instruction signal to the control unit so as to perform the action selected by the action selection step;
an operation result acquisition step of acquiring, after finishing processing a predetermined number of substrates, an operation result including a predetermined number of substrates processed per unit time and a waiting time that elapses until cleaning of a substrate after surface treatment is started in the cleaning unit; and
a prediction model update step of calculating a reward based on an operation result acquired in the operation result acquisition step such that a reward increases as the number of substrates processed increases and the waiting time is short and updating the prediction model based on the reward.

11.-29. (canceled)
